(19) United States
(12) Patent Application Publication
(10) Pub. No.: US 2026/0372058 A1
(43) Pub. Date: Nov. 19, 2026

(54) SEMICONDUCTOR DEVICE AND METHODS OF MANUFACTURING THE SAME

(71) Applicant: Taiwan Semiconductor Manufacturing Company, Ltd., Hsinchu (TW)

(72) Inventors: Chen-Hua Yu, Hsinchu City (TW); Ke-Han Shen, Chiayi City (TW); Kuo-Chung Yee, Taoyuan City (TW); Cheng-Chieh Hsieh, Tainan (TW); Hung-Yi Kuo, Taipei City (TW)

(73) Assignee: Taiwan Semiconductor Manufacturing Company, Ltd., Hsinchu (TW)

(21) Appl. No.: 19/751,099

(22) Filed: Jul. 22, 2026

Related U.S. Application Data
(63) Continuation of application No. 18/664,291, filed on May 15, 2024.

(51) Int. Cl. H10W 20/43; H10B 80/00; H10W 20/20; H10W 20/42; H10W 74/01; H10W 74/10; H10W 80/00; H10W 90/00

(52) U.S. Cl. CPC H10W 20/43; H10B 80/00; H10W 20/20; H10W 20/42; H10W 74/014; H10W 74/141; H10W 80/312; H10W 80/327; H10W 90/792

(57) ABSTRACT

A semiconductor device includes a first tier and a second tier. The first tier includes a semiconductor die, where the semiconductor die includes a plurality of first connecting structures distributed over a non-active side of the semiconductor die. The second tier is disposed over the first tier and includes a memory die, the memory die includes a plurality of second connecting structures distributed over an active side of the memory die. The plurality of first connecting structures are connected to the plurality of second connecting structures in a one-to-one configuration, and the first tier is electrically coupled to the second tier.

### CROSS-REFERENCE TO RELATED APPLICATION

This application is a continuation application of and claims the priority benefit of a prior application serial no. 18/664,291, filed on May 15, 2024. The entirety of the above-mentioned patent application is hereby incorporated by reference herein and made a part of this specification.

### BACKGROUND

Developments in shrinking sizes of semiconductor devices and electronic components make the integration of more devices and components into a given volume possible and lead to high integration density of various semiconductor devices and/or electronic components. Integrated circuit applications currently have increasingly more functions built therein, and are thus formed to be increasingly larger. Accordingly, many types of semiconductor devices and/or electronic components have been developed to suit to customized requirements of integrated circuits.

### BRIEF DESCRIPTION OF THE DRAWINGS

Aspects of the disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-6 are schematic cross-sectional views of various stages in manufacturing a semiconductor device in accordance with some embodiments of the disclosure.

FIGS. 7-13 are schematic, cross-sectional views respectively showing various embodiments of a semiconductor device in accordance with the disclosure.

FIGS. 14-16 are schematic cross-sectional views of various stages in manufacturing a semiconductor device with a semiconductor device in accordance with some embodiments of the disclosure.

FIGS. 17-14 are schematic, cross-sectional views respectively showing various embodiments of a semiconductor device in accordance with the disclosure.

FIG. 25 is a schematic cross-sectional view of a semiconductor package in accordance with some embodiments of the disclosure.

### DETAILED DESCRIPTION

The following disclosure provides many different embodiments, or examples, for implementing different features of the provided subject matter. Specific examples of components, values, operations, materials, arrangements, or the like, are described below to simplify the disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, terms, such as “first”, “second”, “third”, “fourth”, “fifth”, “sixth”, “seventh”, and the like, may be used herein for ease of description to describe similar or different element(s) or feature(s) as illustrated in the figures, and may be used interchangeably depending on the order of the presence or the contexts of the description.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the disclosure provides applicable concepts that can be embodied in a wide variety of specific contexts. The embodiments are intended to provide further explanations but are not used to limit the scope of the disclosure. The specific embodiment(s) described herein is related to a semiconductor device having a stacked structure with one or more memory dies and one or more logic dies electrically coupled and electrically communicated thereto. In some embodiments of the disclosure, the one or more memory dies and the one or more logic dies are integrated into a chiplet form, a short electrical connection between the one or more memory dies and the one or more logic dies can be achieved, thereby improving the performance of the semiconductor device. In addition, the one or more memory dies and the one or more logic dies are integrated into a chiplet form with connecting structures disposed thereon so to greatly improve a routability at the interface of the one or more memory dies and the one or more logic dies inside the semiconductor device. The manufacture of such semiconductor device is compatible to the current and/or advanced manufacturing processes.

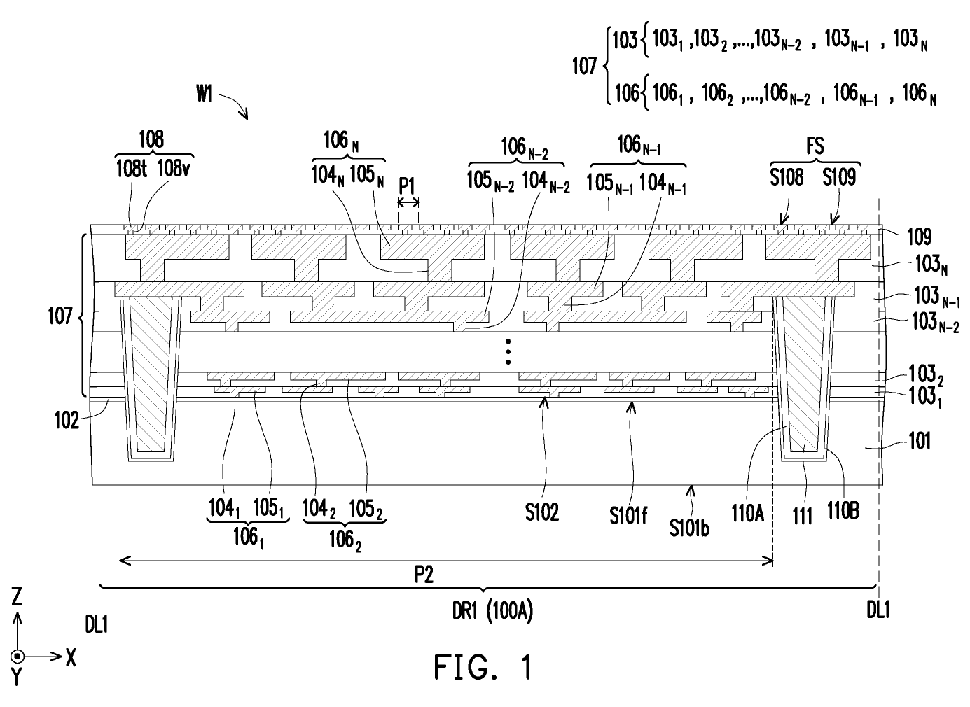

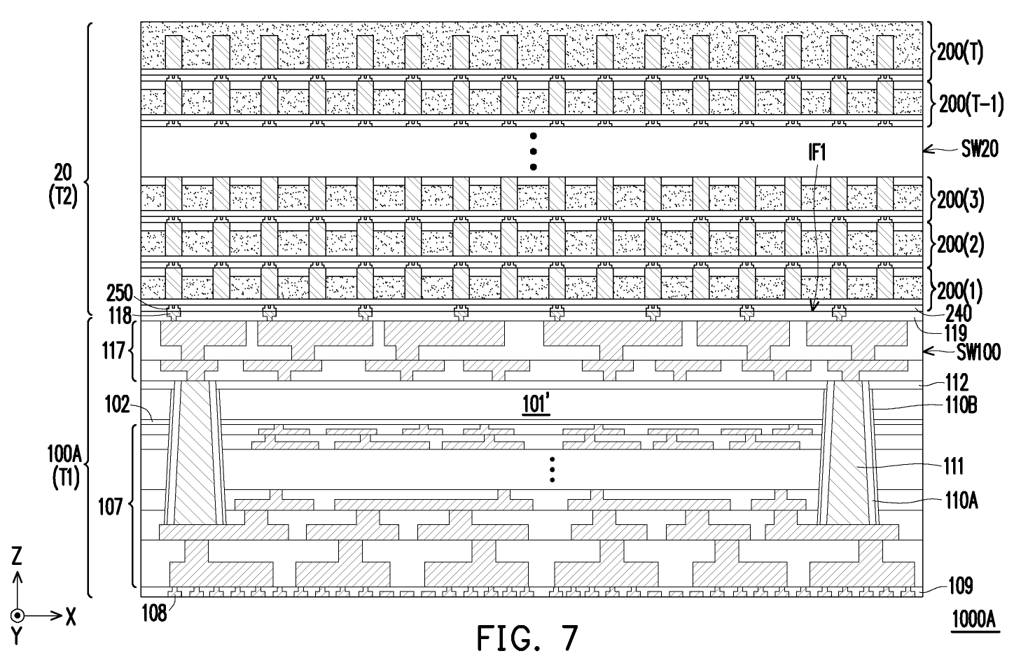

FIGS. 1-6 are schematic cross-sectional views of various stages in manufacturing a semiconductor device (e.g., 10000A) in accordance with some embodiments of the disclosure. FIGS. 7-13 are schematic, cross-sectional views respectively showing various embodiments of a semiconductor device (e.g., 1000A, 10000B, 1000B, 10000C, 1000C, 10000D, or 1000D) in accordance with the disclosure. In some embodiments, the manufacturing method is part of a wafer level packaging process. It is understood that additional processes may be provided before, during, and after the illustrated method, and that some other processes may only be briefly described herein. In the disclosure, it should be appreciated that the illustration of components throughout all figures is schematic and is not in scale. Throughout the various views and illustrative embodiments of the disclosure, the elements similar to or substantially the same as the elements described previously will use the same reference numbers, and certain details or descriptions (e.g., the materials, formation processes, positioning configurations, electrical connections, etc.) of the same elements would not be repeated. For clarity of illustrations, the drawings are illustrated with orthogonal axes (X, Y and Z) of a Cartesian coordinate system according to which the views are oriented; however, the disclosure is not specifically limited thereto.

Referring to FIG. 1, in some embodiments, a wafer W1 is provided. For example, the wafer W1 includes a wide variety of components (not shown) (also referred to as semiconductor components) formed therein. The components may include active components, passive components, or a combination thereof. The components may include integrated circuits devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like. The components each may be referred to as a semiconductor component of the disclosure.

The wafer W1 may be a semiconductor wafer. In some embodiments, if considering a top or plane view (e.g., a X-Y plane) along a direction Z, the wafer W1 is in a wafer or panel form. In other words, the wafer W1 is processed in the form of a reconstructed wafer/panel. The wafer W1 may be in a form of wafer-size having a diameter of about 4 inches or more. The wafer W1 may be in a form of wafer-size having a diameter of about 6 inches or more. The wafer W1 may be in a form of wafer-size having a diameter of about 8 inches or more. Or alternatively, the wafer W1 may be in a form of wafer-size having a diameter of about 12 inches or more. In some embodiments, the wafer W1 includes a plurality of device regions DR1 arranged in a form of an array along a direction X and a direction Y, where each device region DR1 is a positioning (or pre-determined) location for a semiconductor die or chip (e.g., 100A). The direction X, the direction Y and the direction Z may be different from each other. For example, the direction X is perpendicular to the direction Y, and the direction X and the direction Y are independently perpendicular to the direction Z, as shown in FIG. 1. In the disclosure, the direction Z may be referred to as a stacking direction or a vertical direction, the direction X and the direction Y may be referred to as a lateral direction or horizontal direction, and the X-Y plane defined by the direction X and the direction Y may be referred to as the plane view or top view.

In addition, the semiconductor dies 100A of the wafer W1 being formed in different and individual device regions RD are electrically independent from (e.g., electrically isolated from) each other. The semiconductor dies 100A may be referred to as semiconductor dies or chips, independently, including a digital chip, an analog chip, or a mixed signal chip. In some embodiments, the semiconductor dies 100A are, independently, a logic die such as a central processing unit (CPU), a graphics processing unit (GPU), a neural network processing unit (NPU), a deep learning processing unit (DPU), a tensor processing unit (TPU), a system-on-a-chip (SoC), a system-on-integrated circuit (SoIC), an application processor (AP), and a microcontroller; a power management die such as a power management integrated circuit (PMIC) die; a wireless and radio frequency (RF) die; a baseband (BB) die; a sensor die such as a photo/image sensor chip; a micro-electro-mechanical-system (MEMS) die; a signal processing die such as a digital signal processing (DSP) die; a front-end die such as an analog front-end (AFE) dies; an application-specific die such as an application-specific integrated circuit (ASIC), a field-programmable gate array (FPGA); a combination thereof; or the like. In alternative embodiments, the semiconductor dies 100A are, independently, an artificial intelligence (AI) engine such as an AI accelerator; a computing system such as an AI server, a high-performance computing (HPC) system, a high-power computing device, a cloud computing system, a networking system, an edge computing system, an immersive memory computing system (ImMC), a SoIC system, etc.; a combination thereof; or the like. In addition, the semiconductor dies 100A may further, independently, include one or more functions of an electrical and/or optical input/output (I/O) interface die, an integrated passives die (IPD), a voltage regulator (VR) die, a local silicon interconnect (LSI) die with or without deep trench capacitor (DTC) features, a local silicon interconnect (LSI) die with multi-tier functions such as electrical and/or optical network circuit interfaces, IPD, VR, DTC, or the like. The types of the semiconductor dies 100A may be selected and designated based on the demand and design requirement, and thus are not specifically limited in the disclosure. For example, the semiconductor dies 100A includes GPUs.

In some embodiments, the types of all of the semiconductor dies 100A are identical. In alternative embodiments, the types of some of the semiconductor dies 100A are different from each other, while the types of some of the semiconductor dies 100A are identical types. In further alternative embodiments, the types of all of the semiconductor dies 100A are different. In some embodiments, the sizes of all of the semiconductor dies 100A are the same. In alterative embodiments, the sizes of some of the semiconductor dies 100A are different from each other, while the sizes of some of the semiconductor dies 100A are the same sizes. In further alternative embodiments, the sizes of all of the semiconductor dies 100A are different. In some embodiments, the shapes of all of the semiconductor dies 100A are identical. In alternative embodiments, the shapes of some of the semiconductor dies 100A are different from each other, while the shapes of some of the semiconductor dies 100A are identical. In further alternative embodiments, the shapes of all of the semiconductor dies 100A are different. The types, sizes and shapes of each of the semiconductor dies 100A are independent from each other, and may be selected and designed based on the demand and design layout, the disclosure is not limited thereto.

Before a wafer sawing or dicing process along scribe or dicing lines DL1 (shown as dotted lines in the illustrations) is performed on the wafer W1, the device regions DR1 of the wafer W1 are physically connected to one another, as shown in FIG. 1, for example. In FIGS. 1-6, only one device region DR1 (e.g., only one semiconductor device 100A) in the wafer W1 is shown for illustrative purposes, however the disclosure is not limited thereto. The number of the device regions DR1 is not specifically limited in the disclosure, and may be selected and designated based on the demand and/or design requirements.

As shown in FIG. 1, the wafer W1 (e.g., the semiconductor dies 100A included therein) may include a substrate 101, a device layer 102 disposed over the substrate 101, an interconnect 107 disposed over and electrically coupled to the device layer 102, a plurality of connecting structures 108 disposed over and electrically coupled to the interconnect 107, a dielectric layer 109 disposed over the interconnect 107 and laterally covering the connecting structures 108, and a plurality of through vias 111 embedded in and electrically coupled to the interconnect 107 and further extended into the substrate 101.

In some embodiments, the substrate 101 includes a bulk semiconductor substrate, a crystalline silicon substrate, a doped semiconductor substrate (e.g., p-type semiconductor substrate or n-type semiconductor substrate), a semiconductor-on-insulator (SOI) substrate, or the like. In certain embodiments, the substrate 101 includes one or more doped regions or various types of doped regions, depending on design requirements. In some embodiments, the doped regions are doped with p-type and/or n-type dopants. For example, the p-type dopants are boron or BF₂ and the n-type dopants are phosphorus or arsenic. The doped regions may be configured for an n-type metal-oxide-semiconductor (NMOS) transistor or a p-type MOS (PMOS) transistor. The substrate 101 may be1a silicon wafer. Generally, the SOI substrate is a layer of a semiconductor material formed on an insulator layer. The insulator layer is, for example, a buried oxide (BOX) layer, a silicon oxide layer, or the like. Other substrates, such as a multi-layered or a gradient substrate, may also be used. In some alternative embodiments, the substrate 101 includes a semiconductor substrate made of an elemental semiconductor (such as diamond or germanium in a crystalline, a polycrystalline, or an amorphous structure, etc.); a compound semiconductor (such as gallium arsenide, silicon carbide, gallium phosphide, indium phosphide, indium arsenide and/or indium antimonide), an alloy semiconductor (such as silicon-germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), etc.), combinations thereof, or other suitable materials. For example, the substrate 101 is a silicon bulk substrate. The compound semiconductor substrate may have a multilayer structure, or may include a multilayer compound semiconductor structure. The alloy SiGe may be formed over a silicon substrate. The SiGe substrate may be strained.

The device layer 102 may be disposed over the substrate 101, and the components (not shown) formed therein may be or include active components, passive components, other suitable electrical components, and/or combinations thereof. In some embodiments, the components are formed in the device layer 102 disposed at a surface S101f of the substrate 101 proximal to the interconnect 107, the components are formed in the device layer 102 disposed at a surface S101f of the substrate 101 proximal to the interconnect 107 and further partially extended into the substrate 101, or a combination thereof. In some embodiments, as shown in FIG. 1, the surface S101f of the substrate 101 is referred to as an active surface or a front-side of the substrate 101, and a surface S101b of the substrate 101 is referred to as an non-active surface or rear-side of the substrate 101, where the active surface or front-side (e.g., S101f) of the substrate 101 is opposite to the non-active surface or rear-side (e.g., S101b) of the substrate 101 along the direction Z, and the device layer 102 is overlaid on (e.g., in physical contact with) the active surface or front-side (e.g., S101f) of the substrate 101. In some embodiments, the device layer 102 is interposed between the interconnect 107 and the substrate 101. The device layer 102 may include circuitry (not shown) formed in a front-end-of-line (FEOL) fabrication process, and the interconnect 107 may be formed in a back-end-of-line (BEOL) fabrication process.

In some embodiments, the interconnect 107 is disposed over the device layer 102, and the interconnect 107 is electrically coupled to the components formed in the device layer 102. That is, the interconnect 107 provides the routing functions to the components formed in the device layer 102. In some embodiments, at least some of the components formed in the device layer 102 are electrically communicated to one another by the interconnect 107. As shown in FIG. 1, the interconnect 107 may be overlaid over the device layer 102 and includes a plurality of build-up layers being electrically connecting there-between. As shown in FIG. 1, the interconnect 107 is formed on and electrically connected to the device layer 102, for example. In some embodiments, the interconnect 107 includes one or more dielectric layers 103 (e.g., 103₁, 103₂, …, 103_{N-2}, 103_{N-1}, and 103_{N}) and one or more patterned conductive layers 106 (e.g., 106₁, 106₂, …, 106_{N-2}, 106_{N-1}, and 106_{N}). In some embodiments, each patterned conductive layer 106 (e.g., 106₁, 106₂, …, 106_{N-2}, 106_{N-1}, and 106_{N}) includes a line portion 105 (e.g., 105₁, 105₂, …, 105_{N-2}, 105_{N-1}, and 105_{N}) extending along a horizontal direction (e.g., the direction X or the direction Y), a via portion 104 (e.g., 104₁, 104₂, …, 104_{N-2}, 104_{N-1}, and 104_{N}) extending along a vertical direction (e.g., the direction Z), and/or a combination thereof. The patterned conductive layers 106 may be referred to as metallization layers or redistribution layers of the interconnect 107 to provide routing functions, and may be collectively referred to as a routing structure of the interconnect 107. The dielectric layers 103 may be collectively referred to as a dielectric structure of the interconnect 107 to provide protection for the routing structure, the metallization layers or redistribution layers of the interconnect 107. In some embodiments, in the interconnect 107, the dielectric layers (e.g., 103) and the patterned conductive layers (e.g., 106) are arranged in alternation. One dielectric layer and a respective one metallization layer together may be considered as one build-up layer (e.g., 103₁and 106₁; 103₂and 106₂; 103_{N-2} and 106 _{N-2}; 103_{N-1} and 106_{N-1}; 103_{N} and 106_{N}; or the like) of the interconnect 107. As shown in FIG. 1, for example, a topmost layer (e.g., 106_{N}) of the patterned conductive layers 106 may be accessibly revealed by a topmost layer (e.g., 103_{N}) of the dielectric layers 103 for external connection. In the disclosure, the numbers of layers of the dielectric layers 103 and the patterned conductive layers 106 are not limited to what is depicted in FIG. 1, and may be selected and designated based on the demand and design layout. That is, the number (e.g., N) of layers of the dielectric layers (e.g., 103) and the patterned conductive layers (e.g., 106) can be one or greater than one. In some embodiments, line dimensions (e.g., thickness and width) of the patterned conductive layers 106 are gradually increased along a direction from the substrate 101 to the connecting structures 108.

In addition, one or more seed layers (not shown) may be included in the interconnect 107 to facilitate the formation of the patterned conductive layers 106, where the seed layers may be interposed between the patterned conductive layers 106 and the dielectric layers 103. In embodiment of which the seed layers are included, one patterned conductive layer 106 and a respective one seed layer (not shown) may be together referred to as a metallization layer or a redistribution layer of the interconnect 107 to provide routing functions. That is, with such embodiments, one patterned conductive layer 106 and a respective one seed layer (not shown) may be collectively referred to as a routing structure of the interconnect 107.

In some embodiments, the interconnect 107 may be formed by, but not limited to, forming a blanket layer of first dielectric material over the device layer 102; patterning the first dielectric material blanket layer to form a dielectric layer 103₁having a plurality of first openings (not labeled) penetrating there-through and accessibly revealing portions of the device layer 102; optionally forming a blanket layer of first seed layer material over the dielectric layer 103₁, the first seed layer material blanket layer extending into the first openings to line the first openings and in contact with the exposed portions of the device layer 102; forming a blanket layer of a first conductive material over the first seed layer material blanket layer; patterning the first conductive material blanket layer to form a patterned conductive layer 106₁; using the patterned conductive layer 106₁as etching mask to pattern the first seed layer material blanket layer and form a first respective seed layer, thereby forming one build-up layer (e.g., a first build-up layer including 103₁ and 106₁); forming a blanket layer of second dielectric material over the patterned conductive layer 106₁, the dielectric layer 103₁ and the first respective seed layer (if any); patterning the second dielectric material blanket layer to form a dielectric layer 103₂having a plurality of second openings (not labeled) penetrating there-through and accessibly revealing portions of an illustrated top surface of the patterned conductive layer 106₁; optionally forming a blanket layer of second seed layer material over the dielectric layer 103₂, the second seed layer material blanket layer extending into the second openings to line the second openings and in contact with the exposed portions of the patterned conductive layer 106₁; forming a blanket layer of a second conductive material over the second seed layer material blanket layer; patterning the second conductive material blanket layer to form a patterned conductive layer 106₂; using the patterned conductive layer 106₂ as etching mask to pattern the second seed layer material blanket layer and form a second respective seed layer, thereby forming another build-up layer (e.g., a second build-up layer including 103₂ and 106₂); then repeating the formation steps of forming the first and/or second build-up layers to form the rest of build-up layers (e.g., a third build-up layer, a fourth build-up layer, …, a (N-2)^{th} build-up layer (e.g., including 103_{N-2} and 106_{N-2}), a (N-1)^{th} build-up layer (e.g., including 103_{N-1} and 106_{N-1}), and a (N)^{th} build-up layer (e.g., including 103_{N} and 106_{N}). Upon this, the interconnect 107 is manufactured. The interconnect 107 may be formed on the device layer 102 by single or dual damascene process. The disclosure is not limited thereto.

The material of each of the dielectric layers 103 (e.g., 103₁, 103₂, …, 103_{N-2}, 103_{N-1}, and 103_{N}) may be polyimide (PI), polybenzoxazole (PBO), benzocyclobutene (BCB), a nitride such as silicon nitride, an oxide such as silicon oxide, silicon oxynitride, silicon carbon, silicon carbon oxynitride, diamond like carbon (DLC), a high-density plasma (HDP) oxide, phosphosilicate glass (PSG), borosilicate glass (BSG), borophosphosilicate glass (BPSG), undoped silicate glass (USG), tetra-ethyl-ortho-silicate (TEOS), a combination thereof or the like, which may be patterned using a photolithography and/or etching process. The etching process may include a dry etching, a wet etching, or a combination thereof. The dielectric material blanket layer used to form the dielectric layers 103 (e.g., 103₁, 103₂, …, 103_{N-2}, 103_{N-1}, and 103_{N}) may be formed by suitable fabrication techniques such as spin-on coating, chemical vapor deposition (CVD) (e.g., plasma-enhanced chemical vapor deposition (PECVD)), or the like. In one embodiment, the materials of the dielectric layers 103 (e.g., 103₁, 103₂, …, 103_{N-2}, 103_{N-1}, and 103_{N}) are the same to each other. Alternatively, the materials of the dielectric layers 103 (e.g., 103₁, 103₂, …, 103_{N-2}, 103_{N-1}, and 103_{N}) may be different to one another, in part or all.

The optional seed layers individually are referred to as a metal layer, which can be a single layer or a composite layer including a plurality of sub-layers formed of different materials. For example, the optional seed layers each may be or include a titanium layer and a copper layer over the titanium layer. The seed layer material blanket layers used to form the optional seed layers may be formed in a manner of a blanket layer made of metal or metal alloy materials, the disclosure is not limited thereto. The material of each of the optional seed layers material blanket layers may include titanium, copper, molybdenum, tungsten, titanium nitride, titanium tungsten, combinations thereof, or the like, which may be formed using, for example, sputtering, physical vapor deposition (PVD), or the like. The seed layer material blanket layers may be patterned by etching, such as a dry etching process, a wet etching process, or a combination thereof; the disclosure is not limited thereto. In one embodiment, the materials of the optional seed layers are the same to each other. Alternatively, the materials of the optional seed layers may be different to one another.

The material of each of the conductive material blanket layers for forming the patterned conductive layers 106 (e.g., 106₁, 106₂, …, 106_{N-2}, 106_{N-1}, and 106_{N}) may be made of conductive materials formed by electroplating or deposition, such as copper, copper alloy, aluminum, aluminum alloy, or combinations thereof, which may be patterned to form a plurality of conductive patterns/segments using a photolithography and etching process. In some embodiments, the conductive patterns/segments each includes the line portion 105 (e.g., 105₁, 105₂, …, 105_{N-2}, 105_{N-1}, and 105_{N}) extending along a horizontal direction (e.g., the direction X and/or Y) and/or the line portion 105 (e.g., 105₁, 105₂, …, 105_{N-2}, 105_{N-1}, and 105_{N}) extending along the horizontal direction (e.g., the direction X and/or Y) in addition to the via portion 104 (e.g., 104₁, 104₂, …, 104_{N-2}, 104_{N-1}, and 104_{N}) connecting to the line portion 105 (e.g., 105₁, 105₂, …, 105_{N-2}, 105_{N-1}, and 105_{N}) and extending along a vertical direction (e.g., the direction Z). In one embodiment, the materials of the patterned conductive layers 106 (e.g., 106₁, 106₂, …, 106_{N-2}, 106_{N-1}, and 106_{N}) are the same to each other. Alternatively, the materials of the patterned conductive layers 106 (e.g., 106₁, 106₂, …, 106_{N-2}, 106_{N-1}, and 106_{N}) may be different to one another. In addition, the line portions 105 (e.g., 105₁, 105₂, …, 105_{N-2}, 105_{N-1}, and 105_{N}) may be referred to as conductive lines, conductive traces, conductive trenches, metallization lines or traces, routing lines or traces, or redistribution lines or traces, and the via portions 104 (e.g., 104₁, 104₂, …, 104_{N-2}, 104_{N-1}, and 104_{N}) may be referred to as conductive vias, metallization vias, routing vias or redistribution vias.

After forming the build-up layers of the interconnect 107, the connecting structures 108 and the dielectric layer 109 are formed over the dielectric layer 103_{N} and the patterned conductive layer 106_{N}, for example. In some embodiments, the connecting structures 108 are electrically connected to the patterned conductive layer 106_{N} exposed by the dielectric layer 103_{N}. In some embodiments, each connecting structure 108 includes a line portion 108t extending along the horizontal direction (e.g., the direction X or the direction Y), a via portion 108v extending along the vertical direction (e.g., the direction Z), and/or a combination thereof. The formation and material of the dielectric layer 109 are similar to or substantially identical to the formation and material of the dielectric layer 103, the formation and material of the connecting structures 108 (including 108t and 108v) are similar to or substantially identical to the formation and material of the patterned conductive layer 106 (including 105 and 104), and thus are not repeated herein.

For example, as shown in FIG. 1, the connecting structures 108 penetrate through and are laterally covered by the dielectric layer 109, where illustrated top surfaces S108 of the connecting structures 108 are accessibly revealed by the dielectric layer 109. The connecting structures 108 and the dielectric layer 109 may together be referred to as a bonding structure, a bonding layer or a connecting layer of the wafer W1. In some embodiments, the illustrated top surfaces S108 of the connecting structures 108 are substantially level with an illustrated top surface S109 of the dielectric layer 109. In other words, the illustrated top surfaces S108 of the connecting structures 108 are substantially coplanar with the illustrated top surface S109 of the dielectric layer 109. In the disclosure, the illustrated top surfaces S108 of the connecting structures 108 and the illustrated top surface S109 of the dielectric layer 109 together constitute a front-side FS of the wafer W1.

An optional seed layer (not shown) may be formed before forming the connecting structures 108 and after the formation of the dielectric layer 109 so to facilitate the formation of the connecting structures 108. The formation and material of the optional seed layer have been previously described above, and thus are not repeated herein for brevity. In some embodiments, the material of the dielectric layer 109 is different from the materials of one or more of the dielectric layers 103. In other embodiments, the material of the dielectric layer 109 is the same as the materials of the dielectric layers 103.

A pitch P1 between two immediately adjacent connecting structures 108 is less than or substantially equal to 5μm and is greater than 0μm, in some embodiments. The pitch P1 may be greater than 0μm and may be less than or substantially equal to 5.0μm or less, 4.5μm or less, 4.0μm or less, 3.5μm or less, 3.0μm or less, 2.5μm or less, 2.0μm or less, 1.5μm or less, 1.0μm or less, 0.50μm or less, 0.45μm or less, 0.40μm or less, 0.35μm or less, 0.30μm or less, 0.25μm or less, 0.20μm or less, 0.15μm or less, 0.10μm or less, or so on. The number of the connecting structures 108 is not limited in the disclosure, and may be selected and designated based on demand and design layout. The connecting structure 108 may be referred to as conductive terminals or conductor connectors.

In some embodiments, the through vias 111 are formed in the wafer W1 and extending from the interconnect 107 toward to a position inside the substrate 101. For example, the through vias 111 are electrically coupled to the interconnect 107 by direct contact between the patterned conductive layer 106_{N-1} (e.g., 105_{N-1}) and the through vias 111 (e.g., physically connecting illustrated top surfaces of the through vias 111 with an illustrated bottom surface of the patterned conductive layer 106_{N-1}). The wafer W1 may further include a plurality of liners 110A to line sidewalls and illustrated bottom surfaces of the through vias 111. In some embodiments, each of the through vias 111 is covered by a respective liner 110A. For example, the liners 110A are formed between the through vias 111 and the substrate 101, between the through vias 111 and the device layer 102, and between the through vias 111 and a part of the interconnect 107. In some embodiments, the through vias 111 may be tapered from the interconnect 107 to the substrate 101. Alternatively, the through vias 111 have substantially vertical sidewalls. In a cross-sectional view along the direction Z, the shape of the through vias 111 may depend on the design requirements, and is not intended to be limiting in the disclosure. On the other hand, in the top (plane) view on the X-Y plane, the shape of the through vias 111 is circular shape. However, depending on the design requirements, and the shape of the through vias 111 may be an oval shape, a rectangular shape, a polygonal shape, or combinations thereof; the disclosure is not limited thereto. In some embodiments, the liners 110A are not accessibly revealed by the rear surface S101b of the substrate 101.

The through vias 111 may be formed of a conductive material, such as copper, tungsten, aluminum, silver, combinations thereof, or the like. The number of the through vias 111 is not limited in the disclosure, and may be selected and designated based on demand and design layout. The liners 110A may be formed of a barrier material, such as TiN, Ta, TaN, Ti, or the like. The liners 110A may be referred to as barrier layers for the through vias 111. In some embodiments, dielectric liners 110B (e.g., silicon nitride, an oxide, a polymer, a combination thereof, etc.) are further optionally formed between the liners 110A and the substrate 101, between the liners 110A and the device layer 102, and between the liners 110A and a part of the interconnect 107, as shown in FIG. 1. Alternatively, the dielectric liners 110B may be omitted.

The through vias 111, the liners 110A and the dielectric liners 110B may be formed by, but not limited to, forming a plurality of recesses (not label) in the interconnect 107 right before forming the patterned conductive layer 106_{N-1}of the (N-1)^{th} build-up layer of the interconnect 107; respectively depositing the dielectric material, the barrier material and the conductive material in the recesses; and removing excess materials on an plane where illustrated openings of the recesses located at. For example, the recesses are lined with the dielectric liners 110B so as to laterally separate the liners 110A lining the sidewalls and illustrated bottom surfaces of the through vias 111 from the substrate 101, the device layer 102 and a part of the interconnect 107. After the formation of through vias 111, the liners 110A and the dielectric liners 110B, the rest of the components (e.g., 106_{N-1}, 103_{N}, and 106_{N}) of the interconnect 107 are then formed to manufacture the interconnect 107. The through vias 111 are formed by using a via-first approach, in some embodiments. In such embodiments, the through vias 111 are formed prior to the formation of the interconnect 107. Alternatively, the through vias 111 may be formed by using a via-last approach. In some embodiments, the through vias 111 are electrically coupled to the components formed in the device layer 102 through the interconnect 107. It is appreciated that each device region RD is or includes one semiconductor die (or chip) 100.

A pitch P2 between two immediately adjacent through vias 111 may be considered as a large pitch being less than or substantially equal to 30μm and being greater than 10μm, in some embodiments. The pitch P2 may be greater than 10μm and may be less than or substantially equal to 30μm or less, 29μm or less, 28μm or less, 27μm or less, 26μm or less, 25μm or less, 24μm or less, 23μm or less, 22μm or less, 21μm or less, 20μm or less, 19μm or less, 18μm or less, 17μm or less, 16μm or less, 15μm or less, 14μm or less, 13μm or less, 12μm or less, 11μm or less, or so on. In a non-limiting example, the pitch P2 may be substantially equal to 25μm, as shown in FIG. 1. However, the disclosure is not limited thereto.

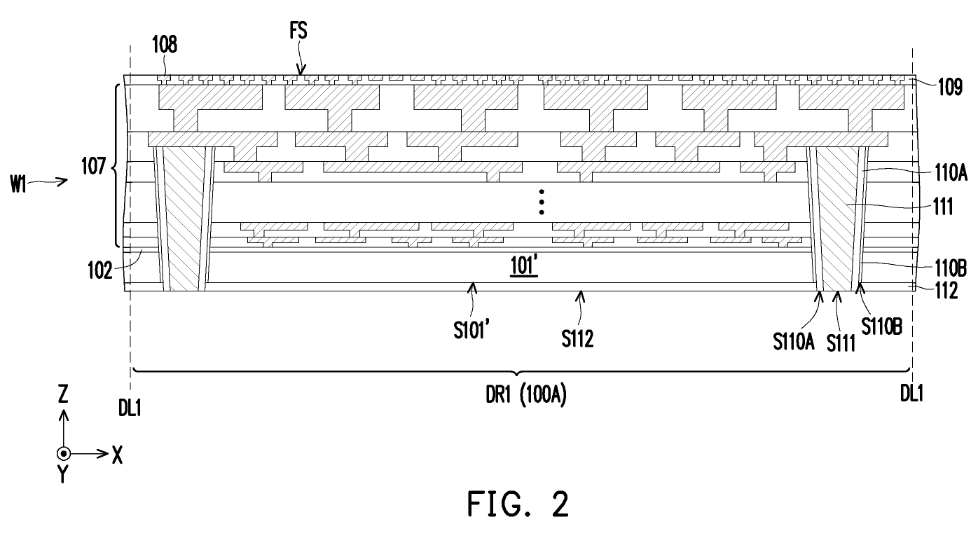

Referring to FIGS. 1 and 2, in some embodiments, a first planarization process is performed to the substrate 101 so to thin down the substrate 101 and accessibly reveal the through vias 111. A portion of the substrate 101, portions of liners 110A and portions of dielectric liners 110B are removed from the wafer W1 so to expose the through vias 111 therefrom, for example. In some cases, during removing the portion of the substrate 101 and the portions of liners 110A and the portions of dielectric liners 110B, portions of the through vias 111 may also be slightly removed. Then, a patterning process is performed on the substrate 101, where the substrate 101 and the dielectric liners 110B are further partially removed so to form a substrate 101’ having a patterned bottom surface S101’ and the dielectric liners 110B having patterned bottom surfaces S110B. In such case, a portion of each of the through vias 111 and a portion of each of the liners 110A protrude from the patterned bottom surface S101’ of the substrate 101’ and the patterned bottom surfaces S110B of the dielectric liners 110B. The patterning process may include an etching process (such as a wet each or a dry etch) or the like, for example. The disclosure is not limited thereto. As shown in FIG. 2, the liners 110A may cover the entire sidewalls of the through vias 111; however, the disclosure is not limited thereto. In one embodiment, the liners 110A may be cover only the sidewalls of the through vias 111 being embedded in the substrate 101’. That is, for example, the liners 110A, which are disposed on the sidewalls of the portions of the through vias 111 protruding from the patterned bottom surface S101’ of the substrate 101’ after the first planarization process, are also removed during the patterning process. The first planarization process may include a grinding process, a chemical mechanical polishing (CMP) process, an etching process, combination thereof, or the like. The etching process may include a dry etching, a wet etching, or a combination thereof.

In some embodiments, a dielectric material (not shown) is formed over the substrate 101’. In some embodiments, the dielectric material is directly formed on the substrate 101’, the through vias 111, the liners 110A and the dielectric liners 110B, where the substrate 101’, the through vias 111, the liners 110A and the dielectric liners 110B are covered by and in physical contact with the dielectric material. In some embodiments, the dielectric material may be formed as a blanket layer of dielectric material. In some embodiments, the dielectric material may be a polymer layer which made of PI, PBO, BCB, or any other suitable polymer-based dielectric material. In some embodiments, the dielectric material may be Ajinomoto Buildup Film (ABF), Solder Resist (SR) film, or the like. In some embodiments, the dielectric material may be formed by a suitable fabrication technique such as spin-coating, lamination, deposition, or the like. Thereafter, a second planarization process is performed on the dielectric material to form a dielectric layer 112 laterally covering the through vias 111 and the liners 110A, where the dielectric layer 112 exposes bottom surfaces S111 of the through vias 111 and bottoms surfaces S110A of the liners 110A and covers the patterned bottom surface S101’ of the substrate 101’ and the patterned bottom surfaces S110B of the dielectric liners 110B. In some embodiments, during the second planarization process, the dielectric material laterally, which is located next to the protruded portions of the through vias 111 and over the patterned bottom surface S101’ of the substrate 101’ and the patterned bottom surfaces S110B of the dielectric liners 110B, are remained, while the rest of the dielectric material are removed. In such case, the remained dielectric material constitutes the dielectric layer 112. In some embodiments, the second planarization process may include a grinding process, a CMP process, an etching process, combination thereof, or the like. The etching process may include a dry etching, a wet etching, or a combination thereof. As shown in FIG. 2, a surface S112 of the dielectric layer 112 is substantially level with the bottom surfaces S111 of the through vias 111 and the bottoms surfaces S110A of the liners 110A, for example. That is, the surface S112 of the dielectric layer 112 is substantially coplanar to the bottom surfaces S111 of the through vias 111 and the bottoms surfaces S110A of the liners 110A.

In some embodiments, after the first and/or second planarization process, a cleaning step may be optionally performed to clean and remove the residue generated from the planarization process. However, the disclosure is not limited thereto, and the first and/or second planarization process may be performed through any other suitable method.

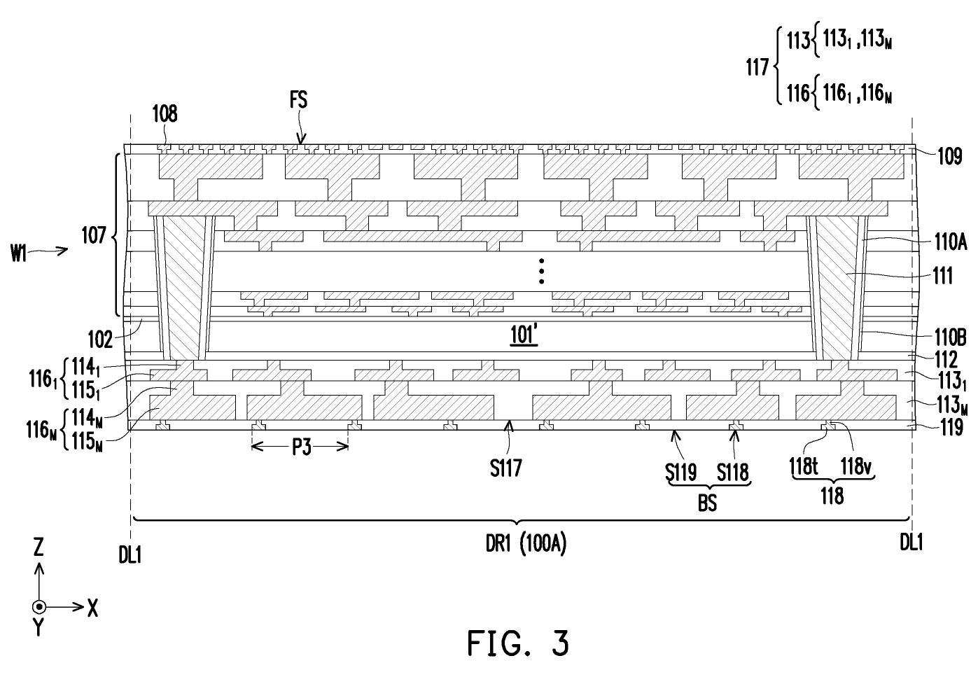

Referring to FIG. 3, in some embodiments, an interconnect 117, a plurality of connecting structures 118 and a dielectric layer 119 are sequentially formed over the substrate 101’. In some embodiments, the interconnect 117 is disposed over the substrate 101’ and on the through vias 111 and the dielectric layer 112, and the interconnect 117 is electrically coupled to the components formed in the device layer 102 through the through vias 111 and the interconnect 107. That is, the interconnect 117 provides further routing functions to the components formed in the device layer 102. As shown in FIG. 3, the interconnect 117 may be overlaid over the through vias 111 and the dielectric layer 112 and includes a plurality of build-up layers being electrically connecting there-between. In some embodiments, the interconnect 117 includes one or more dielectric layers 113 (e.g., 103₁, …, and 113_{M}) and one or more patterned conductive layers 116 (e.g., 116₁, …, and 116_{M}). In some embodiments, each patterned conductive layer 116 (e.g., 116₁, …, and 116_{M}) includes a line portion 115 (e.g., 115₁, …, and 115_{M}) extending along the horizontal direction (e.g., the direction X or the direction Y), a via portion 114 (e.g., 114₁, …, and 114_{M}) extending along the vertical direction (e.g., the direction Z), and/or a combination thereof. The patterned conductive layers 116 may be referred to as metallization layers or redistribution layers of the interconnect 117 to provide routing functions, and may be collectively referred to as a routing structure of the interconnect 117. The dielectric layers 113 may be collectively referred to as a dielectric structure of the interconnect 117 to provide protection for the routing structure, the metallization layers or redistribution layers of the interconnect 117. In some embodiments, in the interconnect 117, the dielectric layers (e.g., 113) and the patterned conductive layers (e.g., 116) are arranged in alternation. One dielectric layer and a respective one metallization layer together may be considered as one build-up layer (e.g., 113₁and 116₁; 103_{M} and 106_{M}; or the like (if any)) of the interconnect 117. As shown in FIG. 3, for example, a topmost layer (e.g., 116_{M}) of the patterned conductive layers 116 may be accessibly revealed by a topmost layer (e.g., 113_{M}) of the dielectric layers 113 for external connection. In the disclosure, the numbers of layers of the dielectric layers 113 and the patterned conductive layers 116 are not limited to what is depicted in FIG. 3, and may be selected and designated based on the demand and design layout. That is, the number (e.g., M) of layers of the dielectric layers (e.g., 113) and the patterned conductive layers (e.g., 116) can be one or greater than one. In some embodiments, line dimensions (e.g., thickness and width) of the patterned conductive layers 116 are gradually increased along a direction from the substrate 101’ to the connecting structures 118.

In addition, one or more seed layers (not shown) may be included in the interconnect 117 to facilitate the formation of the patterned conductive layers 116, where the seed layers may be interposed between the patterned conductive layers 116 and the dielectric layers 113. In embodiment of which the seed layers are included, one patterned conductive layer 116 and a respective one seed layer (not shown) may be together referred to as a metallization layer or a redistribution layer of the interconnect 117 to provide routing functions. That is, with such embodiments, one patterned conductive layer 116 and a respective one seed layer (not shown) may be collectively referred to as a routing structure of the interconnect 117. The formations and materials of the interconnect 117 (including the dielectric layers 113, the optional seed layer and the patterned conductive layer 116 (including the via portion 114 and/or the line portion 115)) are similar to or substantially identical to the formations and materials of the interconnect 107 (including the dielectric layers 103, the optional seed layer and the patterned conductive layer 106 (including the via portion 104 and/or the line portion 105)) as described in FIG. 1, and thus are not repeated herein.

After forming the build-up layers of the interconnec 117, the connecting structures 118 and the dielectric layer 119 are formed over the dielectric layer 113_{N} and the patterned conductive layer 116_{N}, for example. In some embodiments, the connecting structures 118 are electrically connected to the patterned conductive layer 116_{N} exposed by the dielectric layer 113_{N}. In some embodiments, each connecting structure 118 includes a line portion 118t extending along the horizontal direction (e.g., the direction X or the direction Y), a via portion 118v extending along the vertical direction (e.g., the direction Z), and/or a combination thereof. The formation and material of the dielectric layer 119 are similar to or substantially identical to the formation and material of the dielectric layer 109, the formation and material of the connecting structures 118 (including 118t and 118v) are similar to or substantially identical to the formation and material of the connecting structures 108 (including 108t and 108v), and thus are not repeated herein.

For example, as shown in FIG. 3, the connecting structures 118 penetrate through and are laterally covered by the dielectric layer 119, where illustrated top surfaces S118 of the connecting structures 118 are accessibly revealed by the dielectric layer 119. The connecting structures 118 and the dielectric layer 119 may together be referred to as a bonding structure, a bonding layer or a connecting layer of the wafer W1. In some embodiments, the illustrated top surfaces S118 of the connecting structures 118 are substantially level with an illustrated top surface S119 of the dielectric layer 119. In other words, the illustrated top surfaces S118 of the connecting structures 118 are substantially coplanar with the illustrated top surface S119 of the dielectric layer 119. In the disclosure, the illustrated top surfaces S118 of the connecting structures 118 and the illustrated top surface S119 of the dielectric layer 119 together constitute a back-side BS of the wafer W1.

An optional seed layer (not shown) may be formed before forming the connecting structures 118 and after the formation of the dielectric layer 119 so to facilitate the formation of the connecting structures 118. The formation and material of the optional seed layer have been previously described above, and thus are not repeated herein for brevity. In some embodiments, the material of the dielectric layer 119 is different from the materials of one or more of the dielectric layers 103 and/or 113. In other embodiments, the material of the dielectric layer 109 is the same as the materials of the dielectric layers 103 and/or 113.

A pitch P3 between two immediately adjacent connecting structures 118 is less than or substantially equal to 30μm and is greater than 10μm, in some embodiments. The pitch P3 may be greater than 10μm and may be less than or substantially equal to 30μm or less, 29μm or less, 28μm or less, 27μm or less, 26μm or less, 25μm or less, 24μm or less, 23μm or less, 22μm or less, 21μm or less, 20μm or less, 19μm or less, 18μm or less, 17μm or less, 16μm or less, 15μm or less, 14μm or less, 13μm or less, 12μm or less, 11μm or less, or so on. The number of the connecting structures 118 is not limited in the disclosure, and may be selected and designated based on demand and design layout. The connecting structure 118 may be referred to as conductive terminals or conductor connectors. In some embodiments, the pitch P2 of the through vias 111 is greater than the pitch P3 of the connect structures 118. Alternatively, the pitch P2 of the through vias 111 may be less than the pitch P3 of the connect structures 118. Or the pitch P2 of the through vias 111 may be substantially equal to the pitch P3 of the connect structures 118.

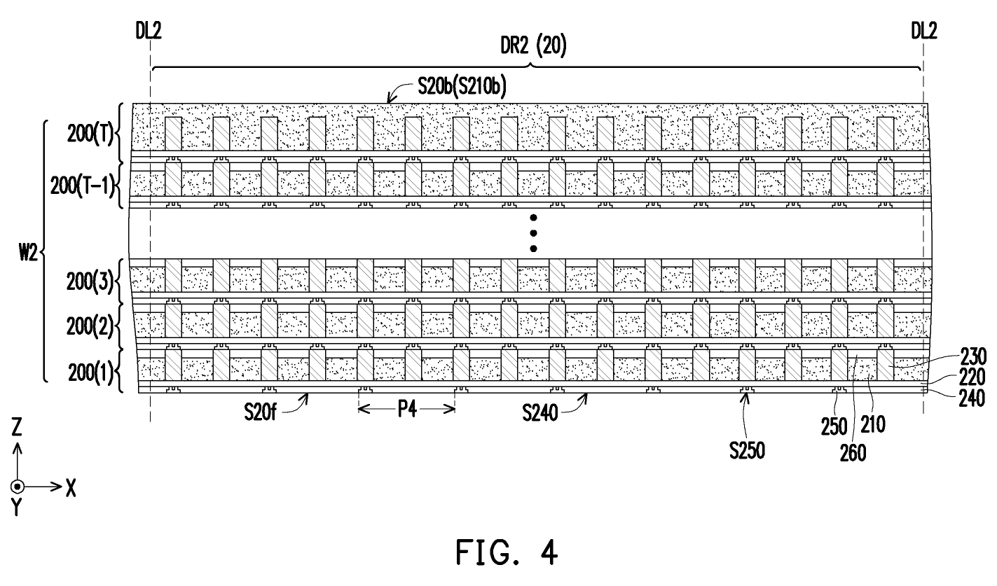

Referring to FIG. 4, in some embodiments, a wafer W2 is provided. For example, the wafer W2 includes a wide variety of components (not shown) (also referred to as semiconductor components) formed therein. The components may include active components, passive components, or a combination thereof. The components may include integrated circuits devices. The components may include transistors, capacitors, resistors, diodes, photodiodes, fuse devices, jumpers, inductors, or other similar devices. The functions of the components may include memory, processors, sensors, amplifiers, power distribution, input/output circuitry, or the like. The components each may be referred to as a semiconductor component of the disclosure. In some embodiments, the wafer W2 is free of active components.

The wafer W2 may be a semiconductor wafer. In some embodiments, if considering a top or plane view (e.g., a X-Y plane) along a direction Z, the wafer W2 is in a wafer or panel form. In other words, the wafer W2 is processed in the form of a reconstructed wafer/panel. The wafer W2 may be in a form of wafer-size having a diameter of about 4 inches or more. The wafer W2 may be in a form of wafer-size having a diameter of about 6 inches or more. The wafer W2 may be in a form of wafer-size having a diameter of about 8 inches or more. Or alternatively, the wafer W2 may be in a form of wafer-size having a diameter of about 12 inches or more. In some embodiments, the wafer W2 includes a plurality of device regions DR2 arranged in a form of an array along a direction X and a direction Y, where each device region DR2 is a positioning (or pre-determined) location for a semiconductor die or chip (e.g., 20). For example, the shape and size of the wafer W2 are substantially identical to the shape and size of the wafer W1.

In some embodiments, the semiconductor dies 20 are, independently, a memory die with a controller or without a controller, where the memory die includes a single-form die such as a dynamic random access memory (DRAM) die, a static random access memory (SRAM) die, a resistive random-access memory (RRAM), a magnetoresistive random-access memory (MRAM), a NAND flash memory, or a wide I/O (WIO) memory; a pre-stacked memory cube such as a hybrid memory cube (HMC) module, a high bandwidth memory (HBM) module; a combination thereof; or the like. For example, the semiconductor dies 20 include HBM modules.

In some embodiments, the types of all of the semiconductor dies 20 are identical. In alternative embodiments, the types of some of the semiconductor dies 20 are different from each other, while the types of some of the semiconductor dies 20 are identical types. In further alternative embodiments, the types of all of the semiconductor dies 20 are different. In some embodiments, the sizes of all of the semiconductor dies 20 are the same. In alterative embodiments, the sizes of some of the semiconductor dies 20 are different from each other, while the sizes of some of the semiconductor dies 20 are the same sizes. In further alternative embodiments, the sizes of all of the semiconductor dies 20 are different. In some embodiments, the shapes of all of the semiconductor dies 20 are identical. In alternative embodiments, the shapes of some of the semiconductor dies 20 are different from each other, while the shapes of some of the semiconductor dies 20 are identical. In further alternative embodiments, the shapes of all of the semiconductor dies 20 are different. The types, sizes and shapes of each of the semiconductor dies 20 are independent from each other, and may be selected and designed based on the demand and design layout, the disclosure is not limited thereto.

Before a wafer sawing or dicing process along scribe or dicing lines DL2 (shown as dotted lines in the illustrations) is performed on the wafer W2, the device regions DR2 of the wafer W2 are physically connected to one another, as shown in FIG. 4, for example. In FIGS. 4-6, only one device region DR2 (e.g., only one semiconductor device 20) in the wafer W2 is shown for illustrative purposes, however the disclosure is not limited thereto. The number of the device regions DR2 is not specifically limited in the disclosure, and may be selected and designated based on the demand and/or design requirements.

As shown in FIG. 4, the wafer W2 may include a plurality of tiers, such as a tier 200(1), a tier 200(2), a tier 200(3), …, a tier 200(T-1) and a tier 200(T), where the tiers are stacked on and electrically coupled to each other. For example, the tier 200(T) is electrically coupled and electrically communicated to the tier 200(1) through the tiers 200(2), 200(3), …, 200(T-1) disposed there-between. In other words, the tiers 200(1) through 200(T) are electrically communicated to each other. In the disclosure, the number of layers of the tiers in the wafer W2 is not limited to what is depicted in FIG. 4; that is, the number (e.g., T) of layers of the tiers (e.g., 103) may be selected and designated based on the demand and design requirements. In some embodiments, in a stacking structure of the wafer W2, the tier 200(1) is considered as a base tier or a bottommost tier of the stacking structure, the tiers 200(2), 200(3), …, and 200(T-1) are considered as inner tiers or stacking tiers of the stacking structure, and the tier 200(T) is the considered as an outermost tier or a topmost tier of a stacking structure.

The base tier (e.g., 200(1)) and the inner tiers (e.g., 200(2), 200(3), …, and 200(T-1)) each may include a semiconductor substrate 210 having semiconductor components (not shown) formed therein, an interconnect 220 formed on the semiconductor substrate 210 and electrically coupled to the semiconductor components, a plurality of through vias 230 formed in the semiconductor substrate 210 and penetrating through the interconnect 220, a dielectric layer 240 formed on the interconnect 220 and opposite to the semiconductor substrate 210, a plurality of connecting structures 250 formed over the interconnect 220, electrically coupled to the through vias 230 and laterally covered by the dielectric layer 240, and a dielectric layer 260 formed over the semiconductor substrate 210 and laterally covering portions of the plurality of through vias 230 protruding out from the semiconductor substrate 210, where the connecting structures 250 may be accessibly revealed by the dielectric layer 240, and the through vias 230 may be accessibly revealed by the semiconductor substrate 210. For example, in the base tier (e.g., 200(1)) and the inner tiers (e.g., 200(2), 200(3), …, and 200(T-1)), surfaces S250 of the connecting structures 250 are substantially level with a surface S240 of the dielectric layer 240, and surfaces (not label) of the through vias 230 are substantially level with a surface (not label) of the dielectric layer 260. In other words, in the base tier (e.g., 200(1)) and the inner tiers (e.g., 200(2), 200(3), …, and 200(T-1)), the surfaces S250 of the connecting structures 250 are substantially level with the surface S240 of the dielectric layer 240, and the surfaces (not label) of the through vias 230 are substantially coplanar with the surface (not label) of the dielectric layer 260. Although it is not illustrated, in the base tier (e.g., 200(1)) and the inner tiers (e.g., 200(2), 200(3), …, and 200(T-1)), sidewalls of the through vias 230 may be lined with a barrier liner (not shown) and a dielectric liner (not shown), where the barrier liner may be disposed between the through vias 230 and the dielectric liner. Alternatively, the dielectric liner may be optional.

On the other hand, the outermost tier (e.g., 200(T)) may include a semiconductor substrate 210 having semiconductor components (not shown) formed therein, an interconnect 220 formed on the semiconductor substrate 210 and electrically coupled to the semiconductor components, a plurality of through vias 230 formed in the semiconductor substrate 210 and extending into the interconnect 220, a dielectric layer 240 formed on the interconnect 220 and opposite to the semiconductor substrate 210, and a plurality of connecting structures 250 formed over the interconnect 220, electrically coupled to the through vias 230 and laterally covered by the dielectric layer 240, where the connecting structures 250 may be accessibly revealed by the dielectric layer 240, and the through vias 230 may not be accessibly revealed by the semiconductor substrate 210. For example, in the outermost tier (e.g., 200(T)), surfaces S250 of the connecting structures 250 are substantially level with a surface S240 of the dielectric layer 240. In other words, in the outermost tier (e.g., 200(T)), the surfaces S250 of the connecting structures 250 are substantially level with the surface S240 of the dielectric layer 240. For example, in the outermost tier (e.g., 200(T)), the through vias 230 are not accessibly revealed by an outermost surface S210b of the semiconductor substrate 210. Although it is not illustrated, in the outermost tier (e.g., 200(T)), bottoms and sidewalls of the through vias 230 may be lined with a barrier liner (not shown) and a dielectric liner (not shown), where the barrier liner may be disposed between the through vias 230 and the dielectric liner. Alternatively, the dielectric liner may be optional.

For example, the semiconductor dies 20 individually has a front side S20f (also referred to as an active surface or an active side) and a back side S20b (also referred to as a non-active surface or a non-active side) opposite to the front side S20f in the direction Z, where the surfaces S250 of the connecting structures 250 and the surface S240 of the dielectric layer 240 of the base tier (e.g., 200(1)) of each the semiconductor die 20 together constitute the front side S20f of each the semiconductor die 20, and the outermost surface S210b of the semiconductor substrate 210 of the outermost tier (e.g., 200(T)) constitutes the back side S20b of each the semiconductor die 20. The formations and materials of the semiconductor structure 210, the interconnect 220, the through vias 230 (with the barrier liner and the dielectric liner), the dielectric layer 240, the connecting structures 250 and the dielectric layer 260 may be similar to or substantially identical to the formations and materials of the substrate 101/101’, the interconnect 107 or 117, the through vias 111 (with the liner 110A and the dielectric liner 110B), the dielectric layer 109/119, the connecting structures 108/118 and the dielectric layer 112 as described in FIGS. 1-3, and thus are not repeated herein for brevity. As shown in FIG. 4, the sidewalls of the through vias 230 may be vertical sidewalls, however the disclosure is not limited thereto. alternatively, the sidewalls of the through vias 230 may be slant sidewalls. The numbers of the through vias 230 and the connecting structure 250 are not limited to the drawings of the disclosure, and may be selected and designated based on the demand and the design requirement.

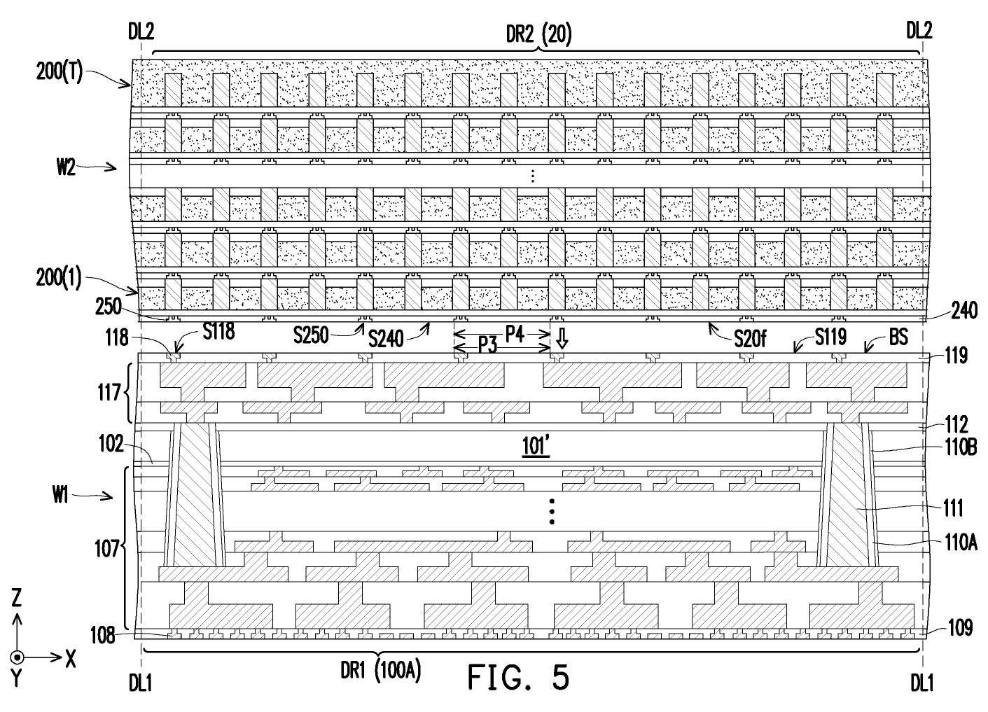

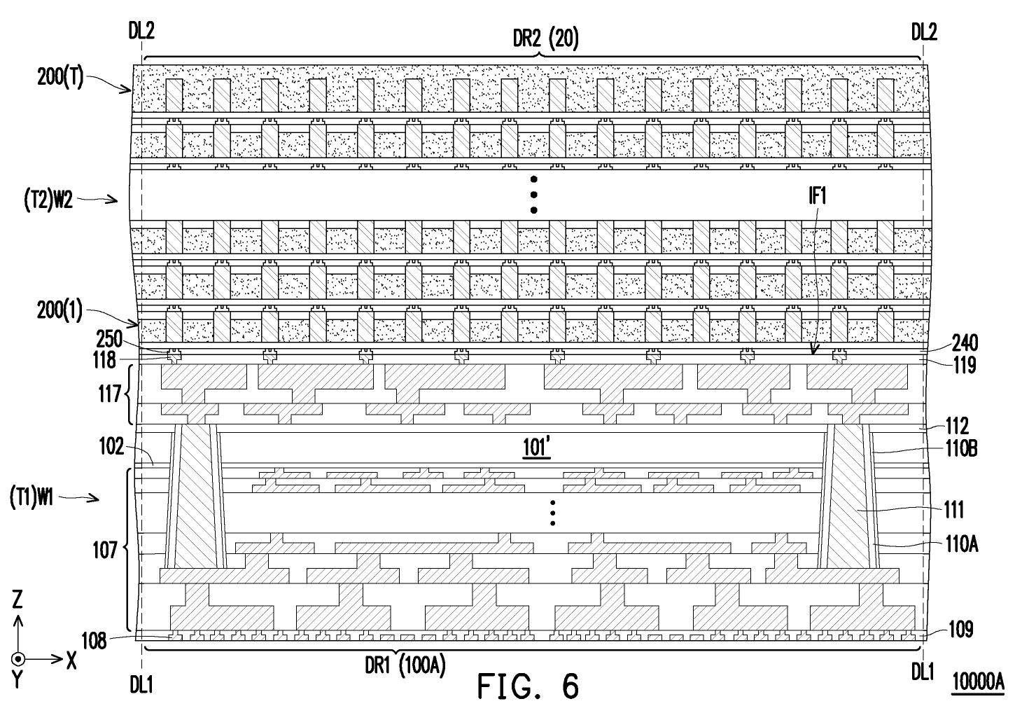

A pitch P4 between two immediately adjacent connecting structures 250 is less than or substantially equal to 30μm and is greater than 10μm, in some embodiments. The pitch P4 may be greater than 10μm and may be less than or substantially equal to 30μm or less, 29μm or less, 28μm or less, 27μm or less, 26μm or less, 25μm or less, 24μm or less, 23μm or less, 22μm or less, 21μm or less, 20μm or less, 19μm or less, 18μm or less, 17μm or less, 16μm or less, 15μm or less, 14μm or less, 13μm or less, 12μm or less, 11μm or less, or so on. The connecting structures 250 and the dielectric layer 240 may together be referred to as a bonding structure, a bonding layer or a connecting layer of the wafer W2. The connecting structure 250 may be referred to as conductive terminals or conductor connectors. In some embodiments, the pitch P4 of the connecting structures 250 is corresponding to the pitch P3 of the connect structures 118, where such configuration allows positioning locations of the connecting structures 250 corresponds positioning locations of the connecting structure 118, during a bonding process (which will be elaborated in FIGS. 5 and 6). In other words, the positioning locations of the connecting structures 250 are overlapped with the positioning locations of the connecting structure 118, respectively.

Referring to FIGS. 5 and 6 together, in some embodiments, the wafer W2 is placed over and bonded to the wafer W1. For example, as shown in FIGS. 5 and 6, each device region DR2 of the wafer W2 is arranged to be overlapped with a respective one device region DR1 of the wafer W1 in the vertical projection along the direction Z. In the case, in the cross-sectional view, the device regions DR2 of the wafer W2 and the device regions DR1 of the wafer W1 are overlapped with one another by a one-to-one configuration. In some embodiments, the wafer W2 is placed over the wafer W1 for bonding by pick-and-place process. As shown in FIGS. 5 and 6, the wafer W2 may be placed over the wafer W1 by having the front side S20f of the semiconductor dies 20 included in the wafer W2 facing towards the back-side BS of the semiconductor dies 100A included in the wafer W1. In some embodiments, the wafer W2 is bonded to the wafer W1 by wafer-on-wafer (WoW) bonding. For example, the wafer W2 is bonded to the wafer W1 by back-to-face configuration. With such bonding configuration (e.g., the back-to-face configuration), a short electrical connection between the semiconductor dies 20 and 100A of the semiconductor device 10000A can be achieved, thereby improving the performance of the semiconductor device 10000A.

For example, the wafer W2 is bonded to the wafer W1 by bonding process including both of a metal-to-metal bonding and a dielectric-to-dielectric bonding. For example, the wafer W2 is disposed on (e.g., in physical contact with) and electrically connected to the wafer W1. In some embodiments, as shown in FIGS. 5 and 6, the connecting structures 250 of the wafer W2 and the connecting structures 118 of the wafer W1 prop against each other and are bonded together through direct metal-to-metal bonding (e.g., such as a ‘copper’-to-‘copper’ bonding). In addition, as shown in FIGS. 5 and 6, the dielectric layer 240 of the wafer W2 and the dielectric layer 119 of the wafer W1 prop against each other and are bonded together through a direct dielectrics-to-dielectrics bonding (such as a ‘oxide’-to-‘oxide’ bonding, a ‘nitride’-to-‘oxide’ bonding, or a ‘nitride’-to-‘nitride’ bonding), for example. In such embodiments, a bonding interface IF1 including a metal-to-metal bonding interface (such as a ‘copper’-to-‘copper’ bonding interface) and a dielectric-to-dielectric bonding interface (such as a ‘oxide’-to-‘oxide’ bonding interface, a ‘nitride’-to-‘oxide’ bonding interface, or a ‘nitride’-to-‘nitride’ bonding interface) are co-existing between the wafer W2 and the wafer W1, and which is considered as a bonding interface of the wafer W2 and the wafer W1.

It should be noted that bonding methods described above are merely examples and are not intended to be limiting. An offset may present between sidewalls of the connecting structures 250 and sidewalls of the connecting structures 118 respectively underlying thereto. Since one of the connecting structures 250 and the connecting structures 118 may have a larger bonding surface than the other one, the direct metal-to-metal bonding may still be achieved even if misalignment occurs, thereby the reliability of electrical connections between the wafer W2 and the wafer W1 can be ensured. With such, for certain embodiments, either the dielectric layer 240 immediately adjacent to the connecting structures 250 is bonded to the connecting structures 118 (e.g., a ‘dielectric’-to-‘metal’ bonding), or the dielectric layer 119 immediately adjacent to the connecting structures 118 is bonded to the connecting structures 250 (e.g., a ‘dielectric’-to-‘metal’ bonding).

In some embodiments, after bonding the wafer W1 and wafer W2, the semiconductor device 10000A having a stacking structure of wafer-form is formed. In such semiconductor device 10000A, the semiconductor dies 20 of the wafer W2 are electrically connected and electrically communicated to the semiconductor dies 100A of the wafer W1, respectively. In addition, the semiconductor dies 20 of the wafer W2 being formed in different and individual device regions DR2 are electrically independent from (e.g., electrically isolated from) each other, and the semiconductor dies 100A of the wafer W1 being formed in different and individual device regions DR1 are electrically independent from (e.g., electrically isolated from) each other. As shown in FIG. 6, the connecting structures 118 and the connecting structure 250 are bonded to each other by a one-to-one configuration, for example. In other words, in the vertical projection (e.g., the X-Y plane), each connecting structure 118 is overlapped with only one respective one connecting structure 250, along the direction Z. Owing to the configuration of the connecting structures 118 (with the pitches P3) and the connecting structures 250 (with the pitches P4), the overall routability at the interface of the semiconductor dies 20 and 100A of the semiconductor device 10000A is greatly improved. As shown in FIG. 6, the wafer W1 of the semiconductor device 10000A may be considered as a first tier T1 of the semiconductor device 10000A, and the wafer W2 of the semiconductor device 10000A may be considered as a second tier T2 of the semiconductor device 10000A, where the connecting structure 108 may be referred to as conductive terminals or conductor connectors of the semiconductor device 10000A for further electrical connections to external components.

However, the disclosure is not limited thereto. Alternatively, a semiconductor device of the disclosure may be formed in a stacking structure of chiplet-form. In some embodiments, a dicing (singulation) process is performed to cut through (e.g., along the scribe lines DL1 and DL2) the wafer W1 and the wafer W2 of the stacking structure of the semiconductor device 10000A so to form a plurality of separated and individual semiconductor devices 1000A, see FIGS. 6 and 7. Referring to FIG. 7, only one semiconductor device 1000A is shown for illustrative purposes. In one embodiment, the dicing (singulation) process is a wafer dicing process including mechanical blade sawing or laser cutting. The disclosure is not limited thereto. In some embodiments, each semiconductor device 1000A includes one semiconductor die 100A (e.g., located in the device regions DR1 of the wafer W1) and one semiconductor die 20 (e.g., located in the device regions DR2 of the wafer W2) stacked thereon, where the semiconductor die 20 is electrically communicated and electrically connected to the semiconductor die 100A by connecting the connecting structures 250 and the connecting structures 118. As shown in FIG. 7, a sidewall SW20 of the semiconductor die 20 and a sidewall SW100 of the semiconductor die 100A may together constitute a sidewall of the semiconductor device 1000A. For example, the semiconductor die 100A of the semiconductor device 1000A may be considered as a first tier T1 of the semiconductor device 1000A, and the semiconductor die 20 of the semiconductor device 1000A may be considered as a second tier T2 of the semiconductor device 1000A, where the connecting structure 108 may be referred to as conductive terminals or conductor connectors of the semiconductor device 1000A for further electrical connections to external components. As shown in FIG. 7, the sidewall SW20 of the semiconductor die 20 is aligned with the sidewall SW100 of the semiconductor die 100A, for example.

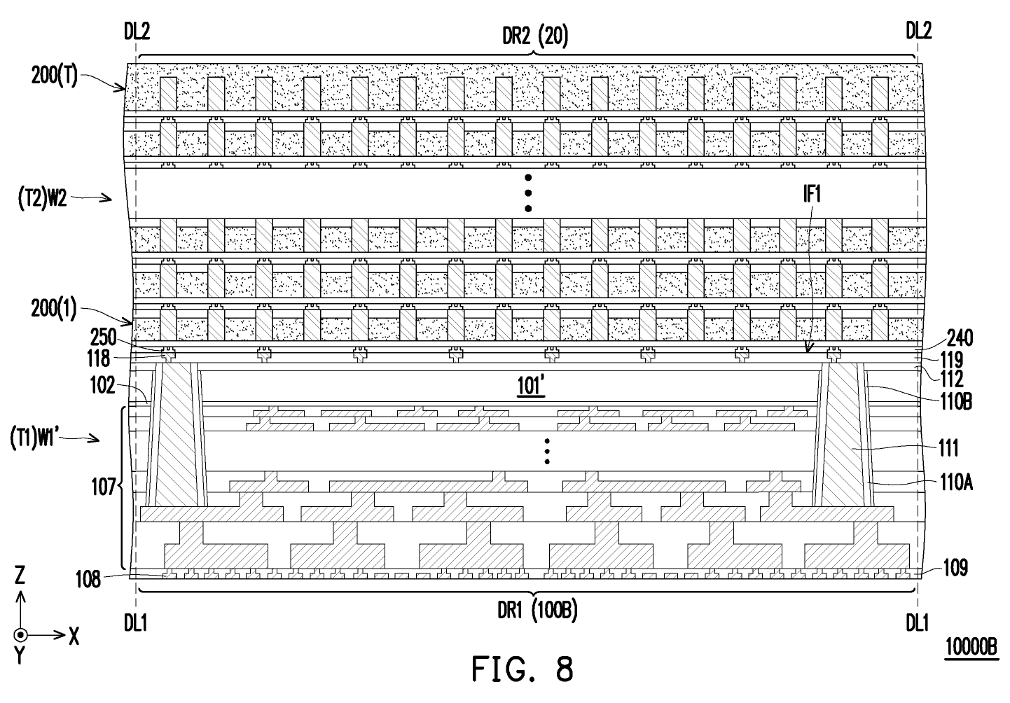

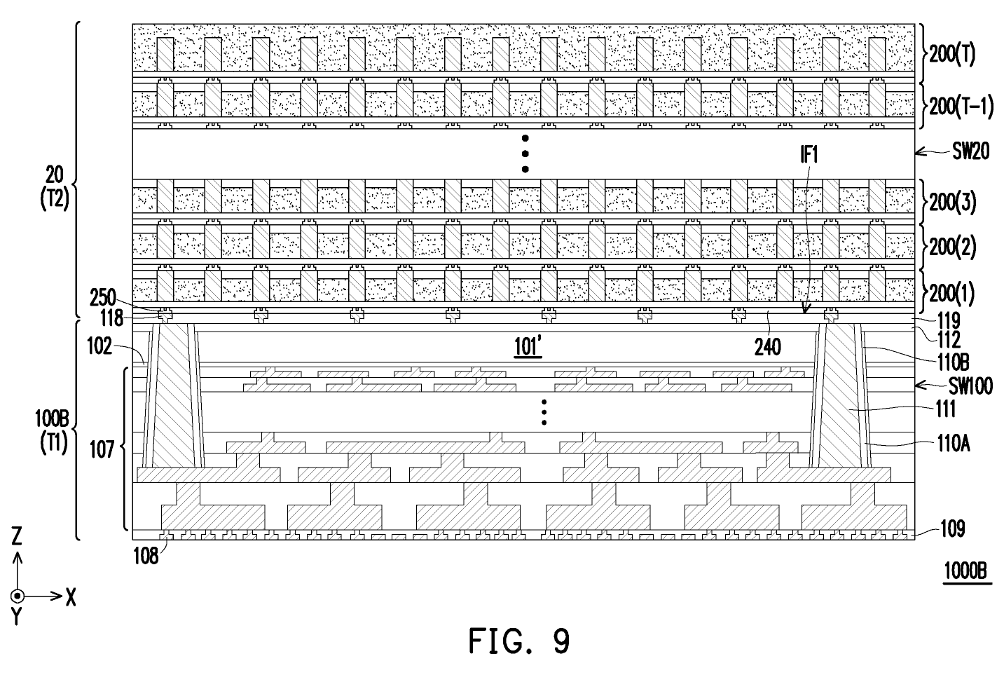

In the embodiments of the semiconductor devices 10000A and 1000A, the through vias 111 are electrically coupled to the connecting structure 118 through the interconnect 117. However, the disclosure is not limited thereto, alternatively, the interconnect 117 can be omitted, see the semiconductor devices 10000B (including a first tier T1 (with a wafer W1’ including a plurality of semiconductor dies 100B) and a second tier T2 (with a wafer W2 including a plurality of semiconductor dies 20)) and 1000B (including a first tier T1 (with a semiconductor die 100B) and a second tier T2 (with a semiconductor die 20)). The semiconductor device 10000B of FIG. 8 is similar to the semiconductor device 10000A of FIG. 6 and the semiconductor device 1000B of FIG. 9 is similar to the semiconductor device 1000A of FIG. 7, a difference is that, in the semiconductor devices 10000B and 1000B, the through vias 111 of the wafer W1’ (or saying the semiconductor die 100B) are electrically coupled to the connecting structure 118 through direct contacts, where the through vias 111 are in physical contact with the connecting structure 118.

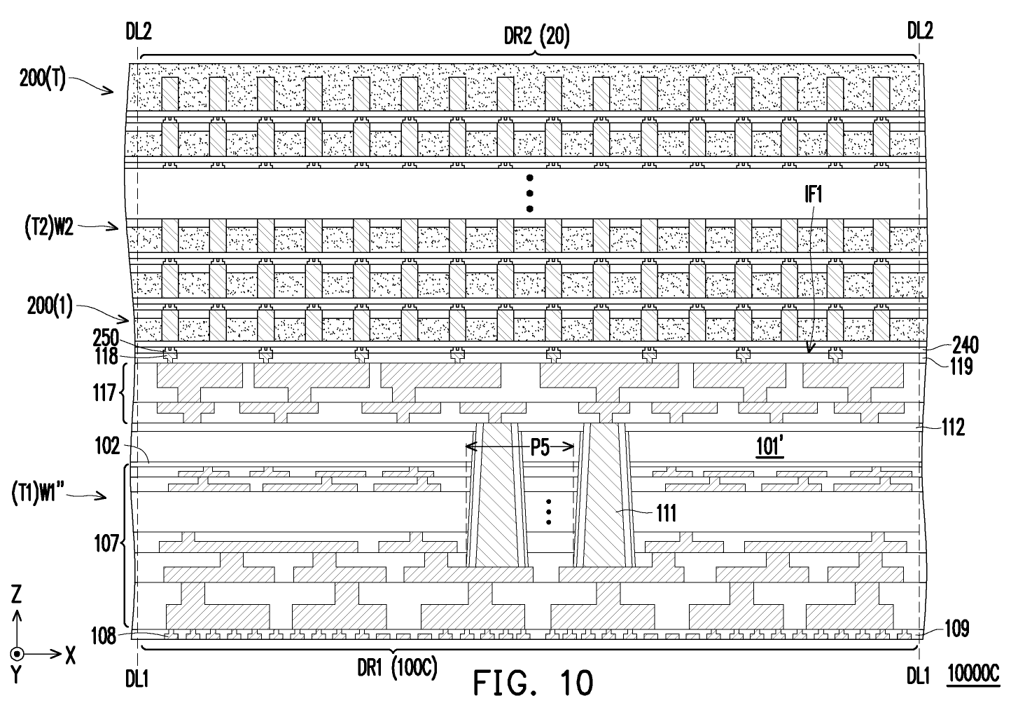

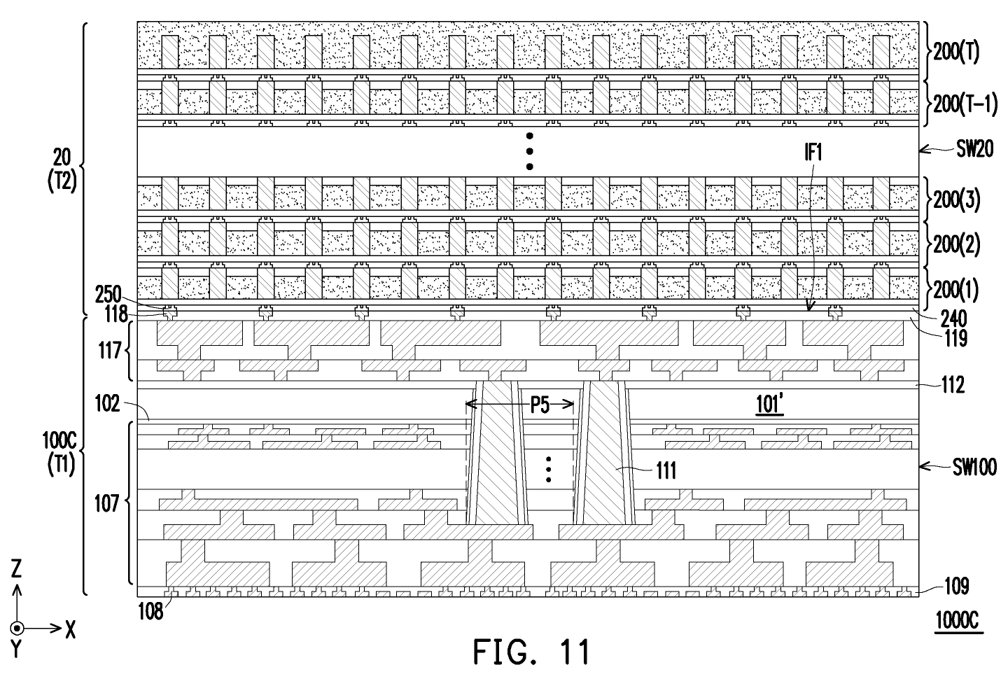

In the embodiments of the semiconductor devices 10000A and 1000A, the pitch P2 between two immediately adjacent through vias 111 is considered as the large pitch. However, the disclosure is not limited thereto, alternatively, a pitch between two immediately adjacent through vias 111 can be a fine (or small) pitch, see the semiconductor devices 10000C (including a first tier T1 (with a wafer W1” including a plurality of semiconductor dies 100C) and a second tier T2 (with a wafer W2 including a plurality of semiconductor dies 20)) and 1000C (including a first tier T1 (with a semiconductor die 100C) and a second tier T2 (with a semiconductor die 20)). The semiconductor device 10000C of FIG. 10 is similar to the semiconductor device 10000A of FIG. 6 and the semiconductor device 1000C of FIG. 11 is similar to the semiconductor device 1000A of FIG. 7, a difference is that, in the semiconductor devices 10000C and 1000C, the through vias 111 has a pitch P5, where the pitch P5 between two immediately adjacent through vias 111 may be considered as a fine (or small) pitch being less than or substantially equal to 10μm and is greater than 0μm, in some embodiments. The pitch P5 may be greater than 0μm and may be less than or substantially equal to 10μm or less, 9.5μm or less, 9μm or less, 8.5μm or less, 8μm or less, 7.5μm or less, 7μm or less, 6.5μm or less, 6.0μm or less, 5.5μm or less, 5.0μm or less, 4.5μm or less, 4.0μm or less, 3.5μm or less, 3.0μm or less, 2.5μm or less, 2.0μm or less, 1.5μm or less, 1.0μm or less, 0.5μm or less, or so on. In a non-limiting example, the pitch P5 may be substantially equal to 6μm. In some embodiments, the pitch P5 of the through vias 111 is less than the pitch P3 of the connect structures 118. Alternatively, the pitch P5 of the through vias 111 may be greater than the pitch P3 of the connect structures 118. Or the pitch P5 of the through vias 111 may be substantially equal to the pitch P3 of the connect structures 118.

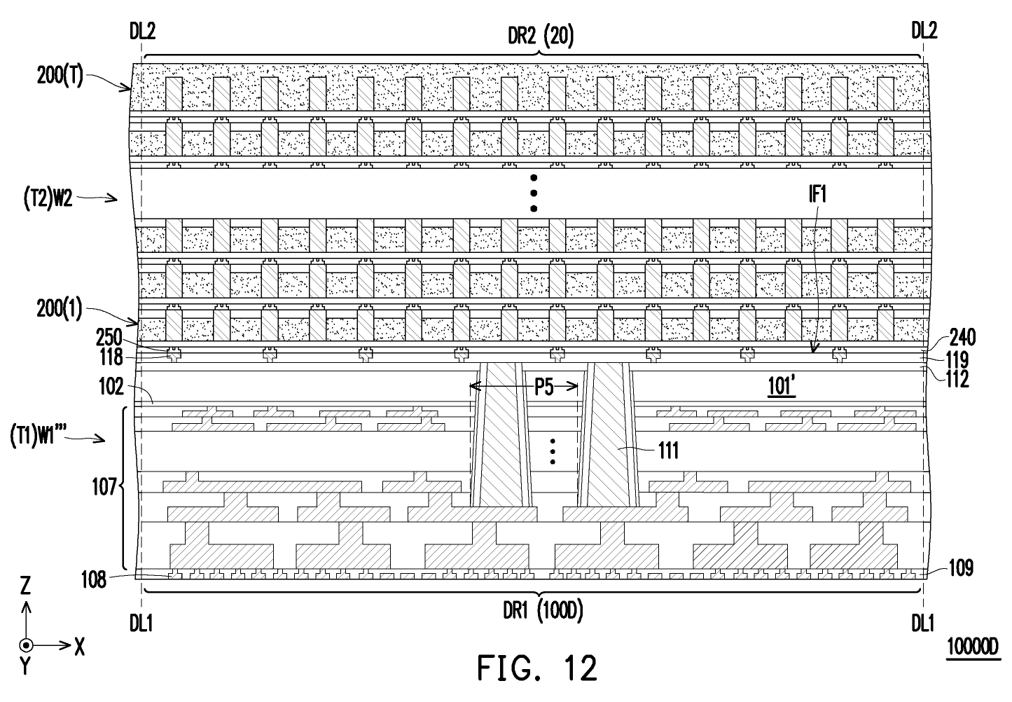

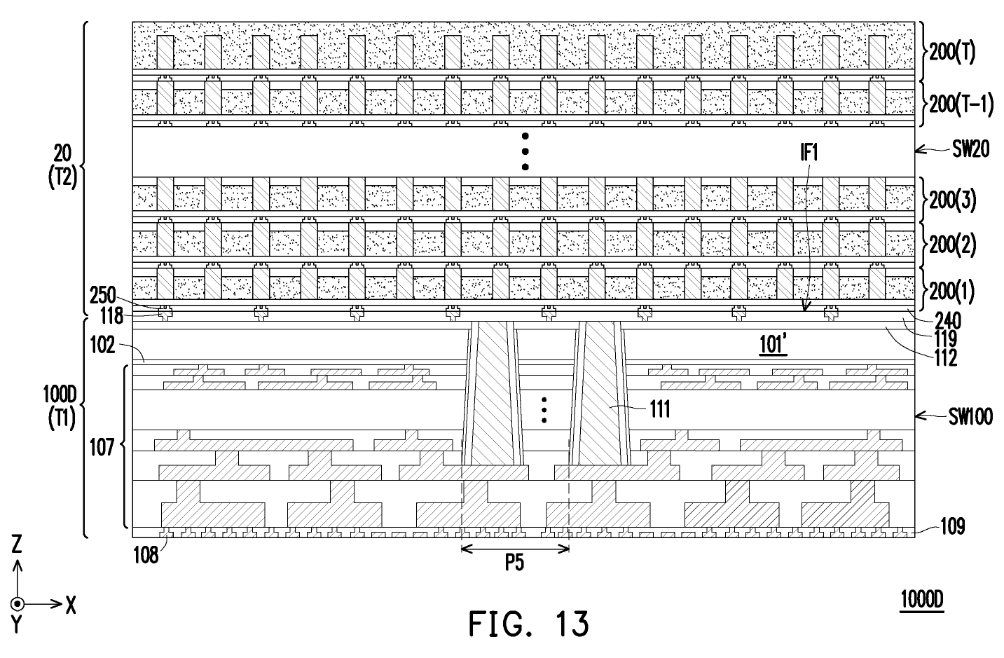

Similarly, in the embodiments of the semiconductor devices 10000C and 1000C, the through vias 111 are electrically coupled to the connecting structure 118 through the interconnect 117. However, the disclosure is not limited thereto, alternatively, the interconnect 117 can be omitted, see the semiconductor devices 10000D (including a first tier T1 (with a wafer W1”’ including a plurality of semiconductor dies 100D) and a second tier T2 (with a wafer W2 including a plurality of semiconductor dies 20)) and 1000D (including a first tier T1 (with a semiconductor die 100D) and a second tier T2 (with a semiconductor die 20)). The semiconductor device 10000D of FIG. 12 is similar to the semiconductor device 10000C of FIG. 10 and the semiconductor device 1000D of FIG. 13 is similar to the semiconductor device 1000C of FIG. 11, a difference is that, in the semiconductor devices 10000D and 1000D, the through vias 111 are electrically coupled to the connecting structure 118 through direct contacts, where the through vias 111 are in physical contact with the connecting structure 118.

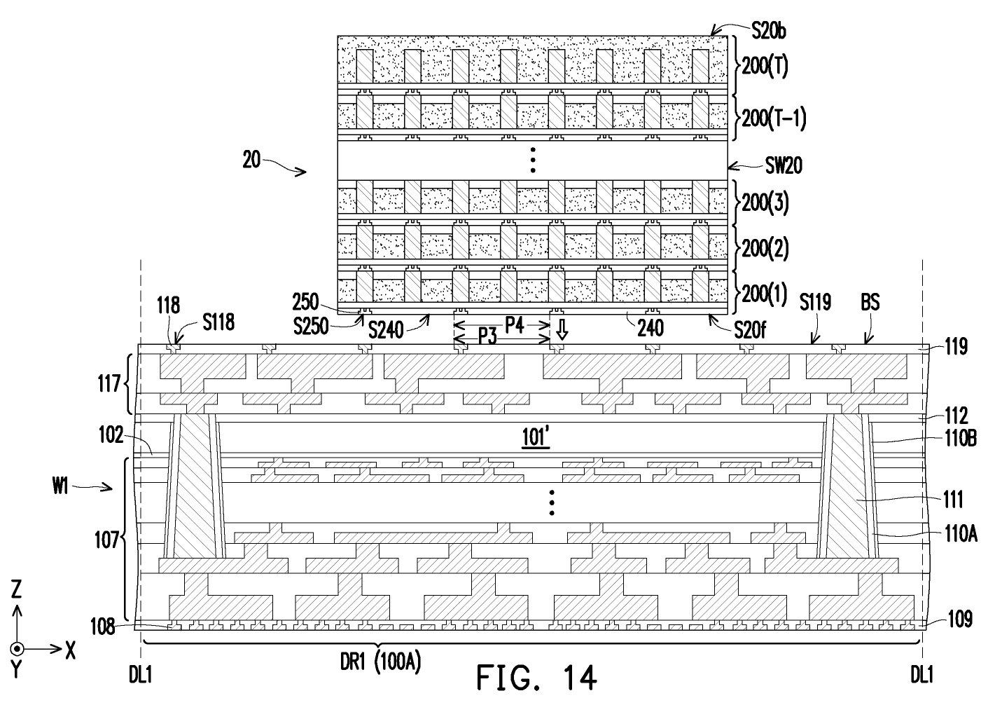

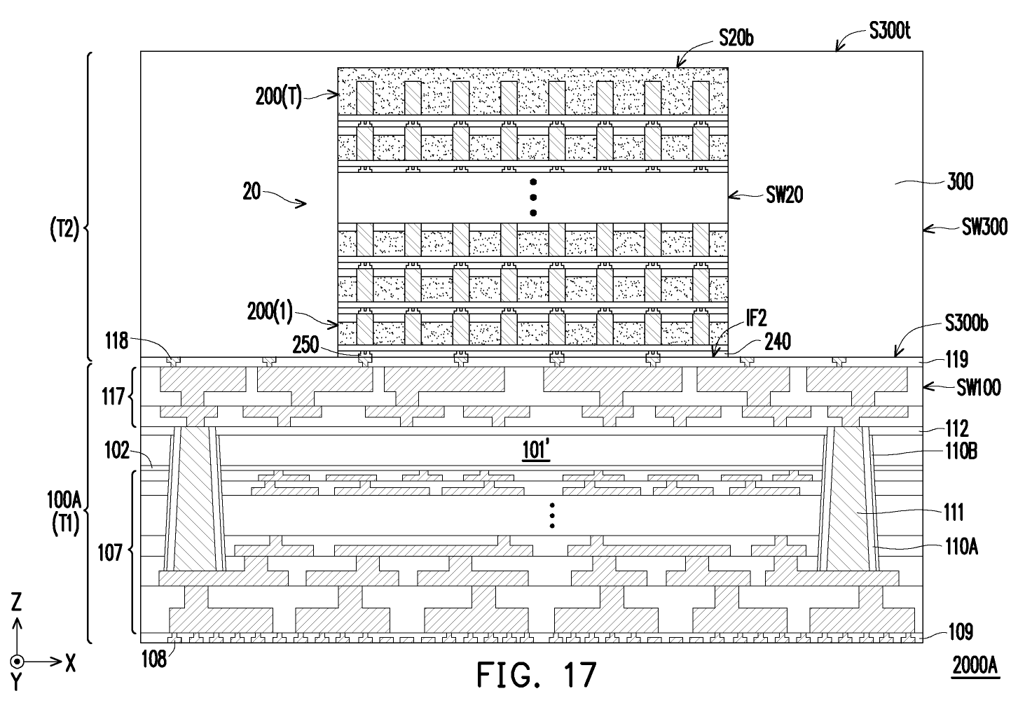

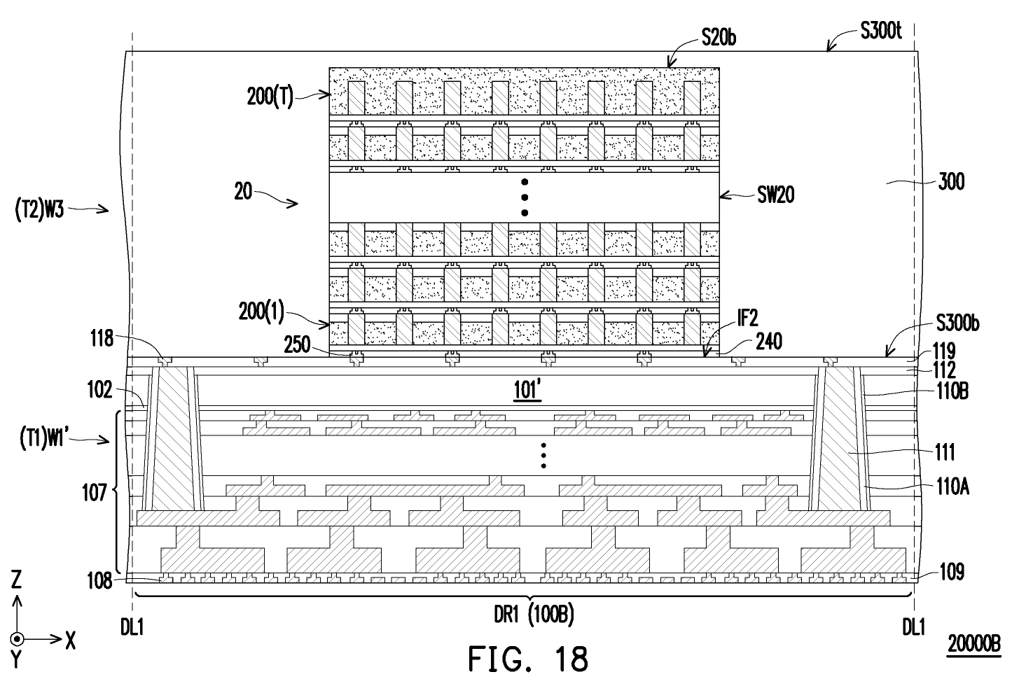

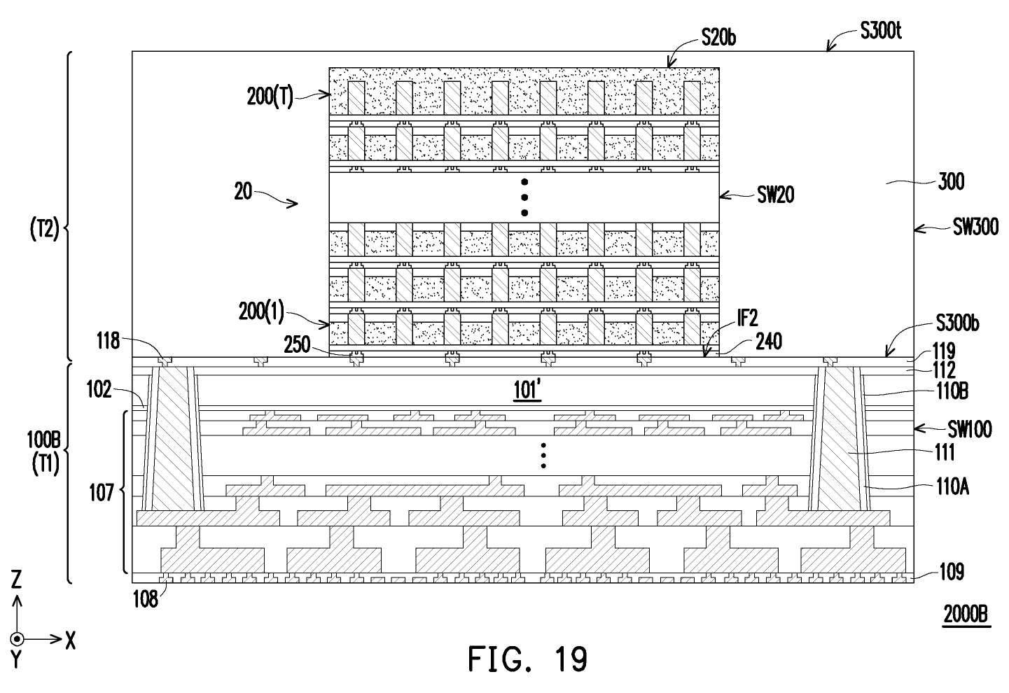

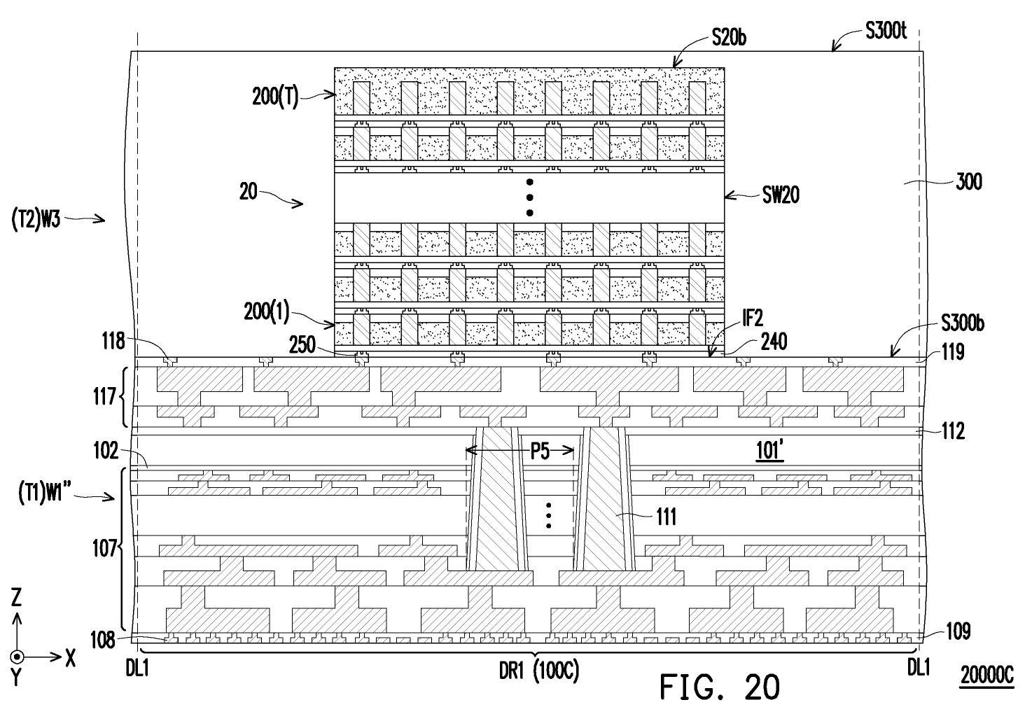

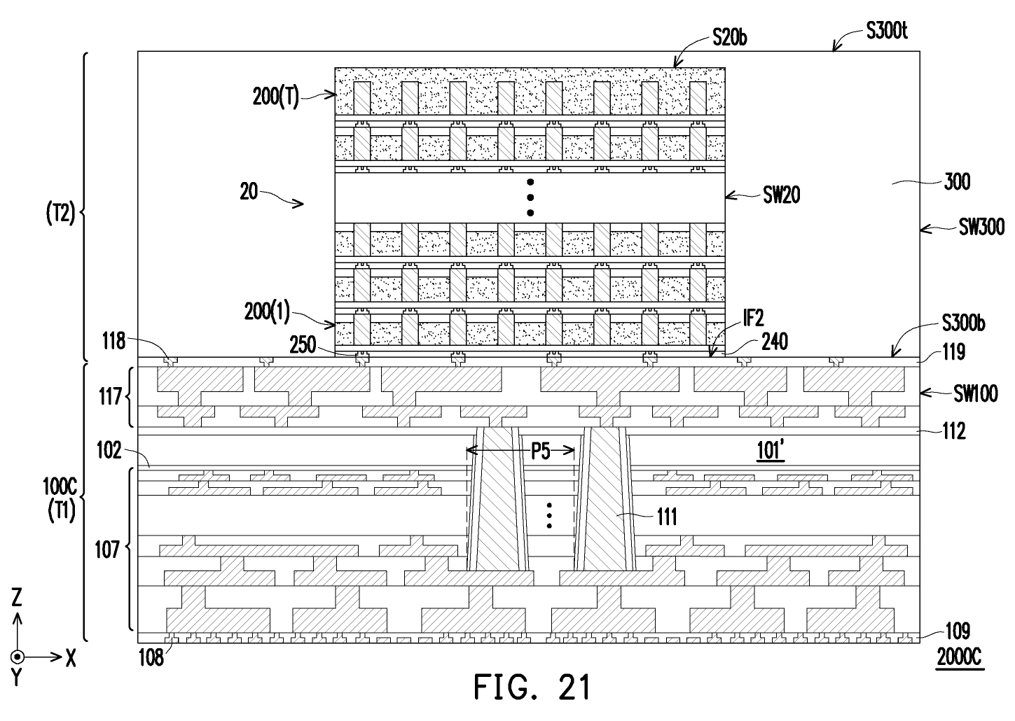

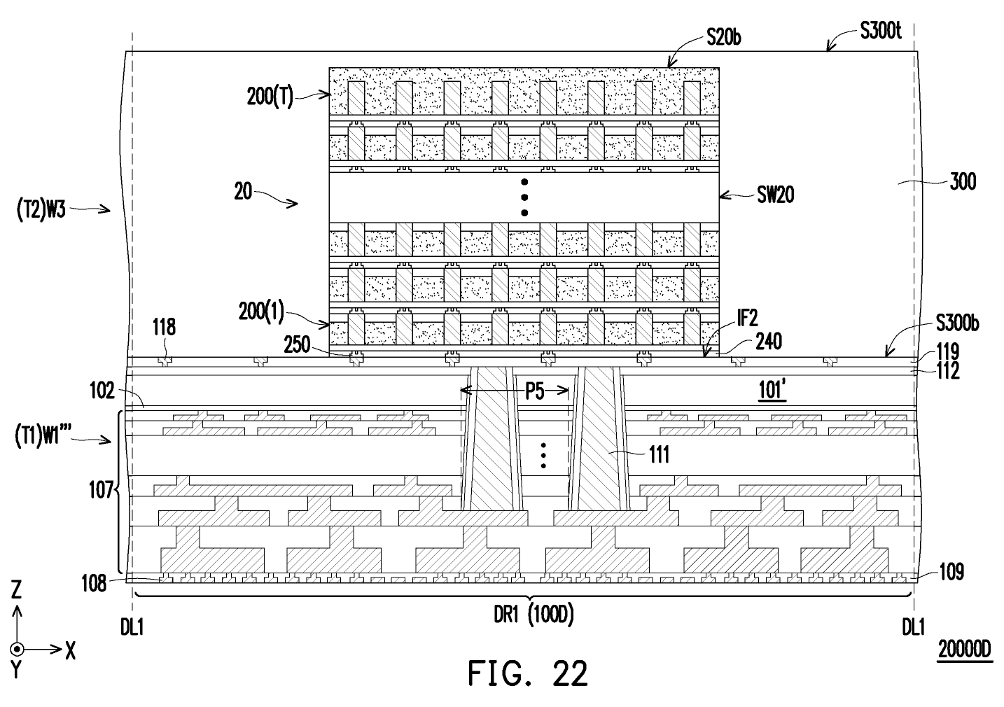

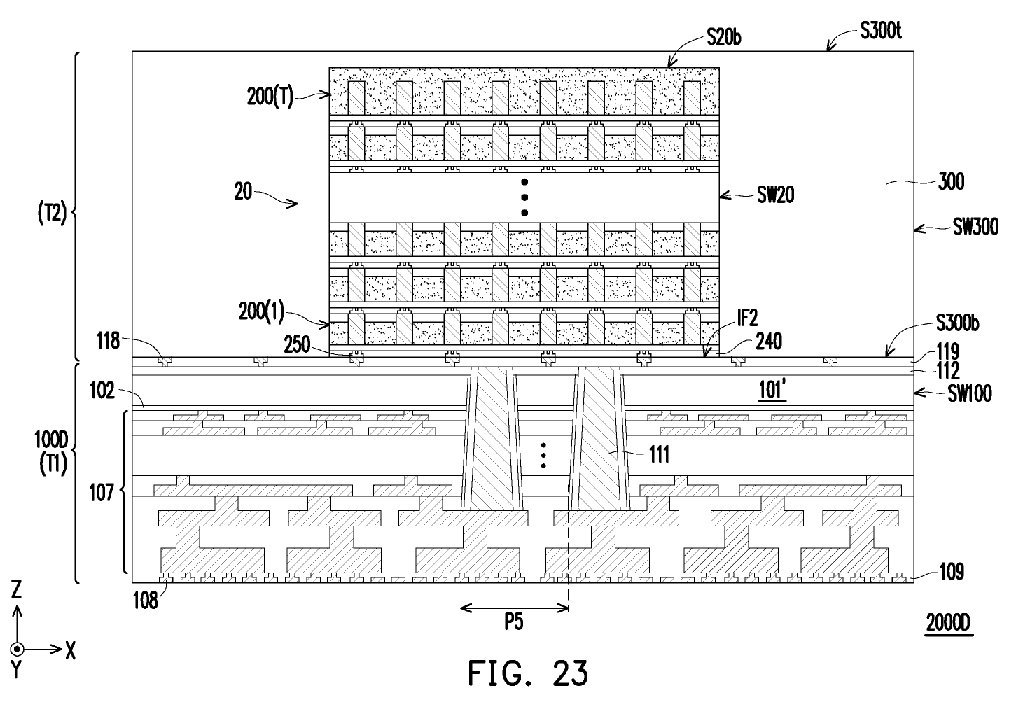

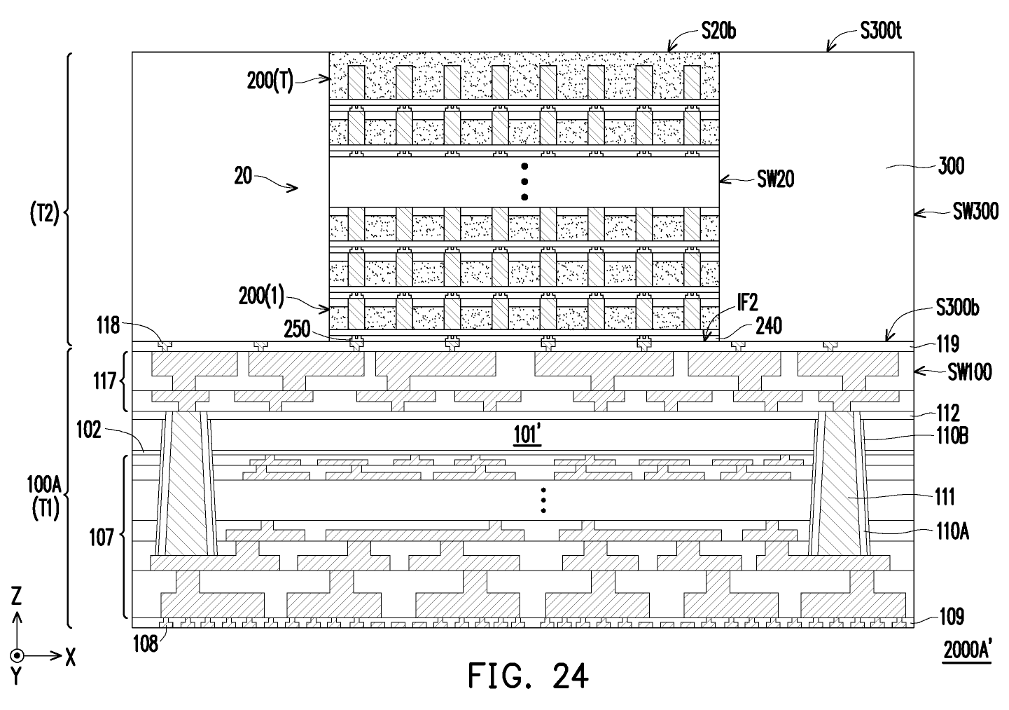

FIGS. 14-16 are schematic cross-sectional views of various stages in manufacturing a semiconductor device with a semiconductor device (e.g., 20000A) in accordance with some embodiments of the disclosure. FIGS. 17-24 are schematic, cross-sectional views respectively showing various embodiments of a semiconductor device (e.g., 2000A, 20000B, 2000B, 20000C, 2000C, 20000D, 2000D, or 2000A’) in accordance with the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 14, in some embodiments, a plurality of separated and individual semiconductor dies 20 are picked and placed on the wafer W1 including a plurality of semiconductor dies 100A, following the process as described in FIG. 3. The details of the semiconductor dies 100A and the semiconductor dies 20 have been previously discussed in FIGS. 1-6, and thus are not repeated herein for brevity. In some embodiments, the semiconductor dies 20 are diced from the wafer W2 depicted in FIG. 4 by dicing (or singulation) process. The number of the semiconductor dies 20 and the number of the semiconductor dies 100A may be more than two. The number of the semiconductor dies 20 and the number of the semiconductor dies 100A, independently, may be selected and designated based on the demand or design layout. The number of the semiconductor dies 20 may correspond to the number of the semiconductor dies 100A in the device regions DR1 included in the wafer W1. For one non-limiting example, the semiconductor dies 20 are overlapped with the semiconductor dies 100A (e.g., located in the device regions DR1 of the wafer W1) in a manner of one-to-one configuration, in the direction Z, as shown in FIG. 14. As shown in FIG. 14, the semiconductor dies 20 may be placed over the wafer W1 by having the front side S20f of one semiconductor die 20 facing towards the back-side BS of a respective one semiconductor die 100A included in the wafer W1. For illustrative purposes, only one semiconductor die 100A in the wafer W1 and only one semiconductor die 20 are shown in FIGS. 14-16 for simplicity, however the disclosure is not limited thereto.

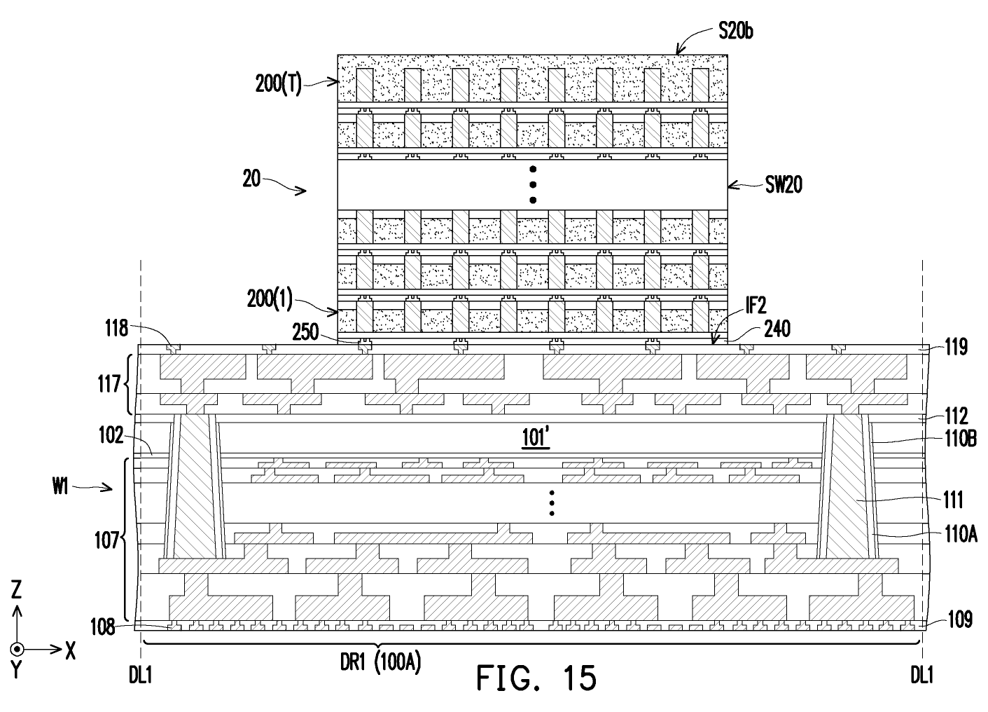

Referring to FIG. 15, in some embodiments, after the placement of the semiconductor die 20, a bonding process is performed to bond the semiconductor die 20 onto a respective one semiconductor die 100A of the wafer W1 overlapped therewith along the direction Z. For example, the semiconductor die 20 is bonded to the wafer W1 by bonding process including both of a metal-to-metal bonding and a dielectric-to-dielectric bonding. For example, the semiconductor die 20 is disposed on (e.g., in physical contact with) and electrically connected to the wafer W1. In some embodiments, as shown in FIG. 15, the connecting structures 250 of the semiconductor die 20 and the connecting structures 118 of the semiconductor die 100A in the wafer W1 prop against each other and are bonded together through direct metal-to-metal bonding (e.g., such as a ‘copper’-to-‘copper’ bonding). In addition, as shown in FIG. 15, the dielectric layer 240 of the semiconductor die 20 and the dielectric layer 119 of the semiconductor die 100A in the wafer W1 prop against each other and are bonded together through a direct dielectrics-to-dielectrics bonding (such as a ‘oxide’-to-‘oxide’ bonding, a ‘nitride’-to-‘oxide’ bonding, or a ‘nitride’-to-‘nitride’ bonding), for example. In such embodiments, a bonding interface IF2 including a metal-to-metal bonding interface (such as a ‘copper’-to-‘copper’ bonding interface) and a dielectric-to-dielectric bonding interface (such as a ‘oxide’-to-‘oxide’ bonding interface, a ‘nitride’-to-‘oxide’ bonding interface, or a ‘nitride’-to-‘nitride’ bonding interface) are co-existing between the semiconductor die 20 and the wafer W1, and which is considered as a bonding interface of the semiconductor die 20 and the wafer W1.

It should be noted that bonding methods described above are merely examples and are not intended to be limiting. An offset may present between sidewalls of the connecting structures 250 and sidewalls of the connecting structures 118 respectively underlying thereto. Since one of the connecting structures 250 and the connecting structures 118 may have a larger bonding surface than the other one, the direct metal-to-metal bonding may still be achieved even if misalignment occurs, thereby the reliability of electrical connections between the semiconductor die 20 and the wafer W can be ensured. With such, for certain embodiments, either the dielectric layer 240 immediately adjacent to the connecting structures 250 is bonded to the connecting structures 118 (e.g., a ‘dielectric’-to-‘metal’ bonding), or the dielectric layer 119 immediately adjacent to the connecting structures 118 is bonded to the connecting structures 250 (e.g., a ‘dielectric’-to-‘metal’ bonding).

In some embodiments, the semiconductor die 20 is bonded to the wafer W1 by chip-on-wafer (CoW) bonding. For example, the semiconductor die 20 is bonded to the wafer W1 by back-to-face configuration. With such bonding configuration (e.g., the back-to-face configuration), a short electrical connection between the semiconductor dies 20 and 100A of the semiconductor device 20000A can be achieved, thereby improving the performance of the semiconductor device 20000A. In the embodiments of which the semiconductor dies 20 are overlapped with the semiconductor dies 100A (e.g., located in the device regions DR1 of the wafer W1) in a manner of one-to-one configuration, the single semiconductor die 20 overlying each semiconductor die 100A is electrically independent from (e.g., electrically isolated from) from each other.

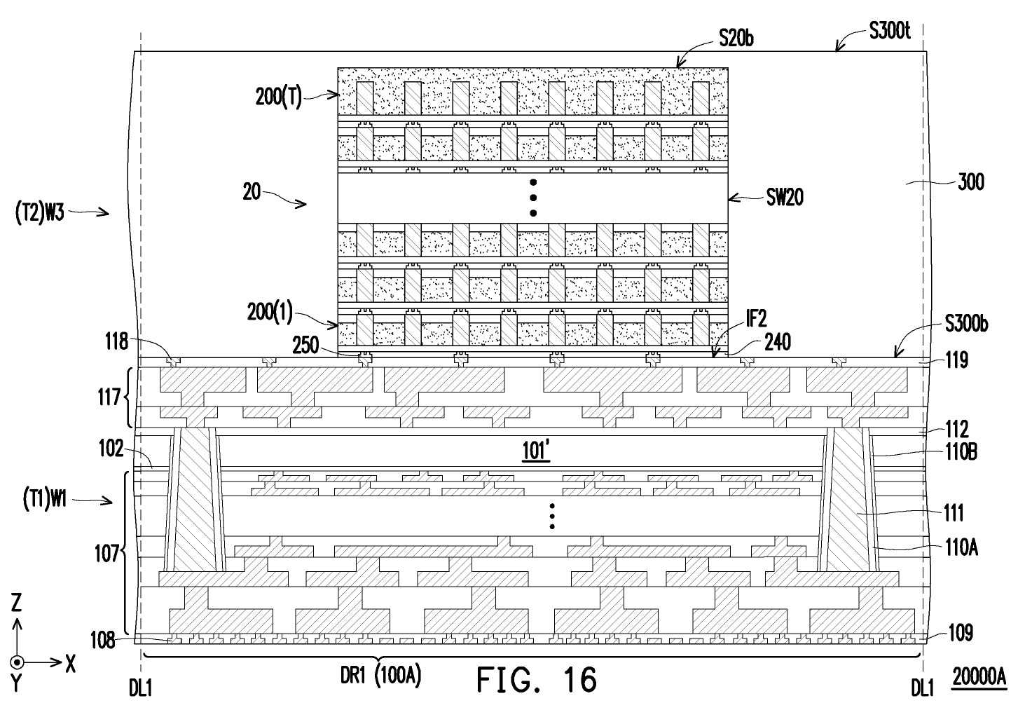

Referring to FIG. 16, in some embodiments, the semiconductor die 20 is encapsulated in an insulating material. In some embodiments, an insulating encapsulation 300 is conformally formed on the semiconductor die 20 and over the wafer W1 exposed by the semiconductor die 20 so to form a wafer W3, where the semiconductor die 20 and the wafer W1 exposed by the semiconductor die 20 are completely covered by the insulating encapsulation 300. As shown in FIG. 16, the wafer W3 includes the semiconductor die 20 and the insulating encapsulation 300, and the semiconductor die 20 is not accessibly revealed by the insulating encapsulation 300, for example. As shown in FIG. 16, the back side S20b of the semiconductor dies 20 may not be exposed by a surface S300t of the insulating encapsulation 300, where a sidewall SW20 of the semiconductor die 20 is covered by (e.g., in physical contact with) the insulating encapsulation 300. In some embodiments, a surface S300b of the of the insulating encapsulation 300 is opposite to the surface S300t of the insulating encapsulation 300 in the direction Z, where the surface S300b of the of the insulating encapsulation 300 is disposed on (e.g., in physical contact with) the rear-side BS of the wafer W1.

In some embodiments, after forming the wafer W3 over the wafer W1, the semiconductor device 20000A having a stacking structure of wafer-form is formed. In such semiconductor device 20000A, the semiconductor dies 20 of the wafer W3 are electrically connected and electrically communicated to the semiconductor dies 100A of the wafer W1, respectively. In addition, the semiconductor dies 20 of the wafer W3 overlying the semiconductor dies 100A of the wafer W1 being formed in different and individual device regions DR1 are electrically independent from (e.g., electrically isolated from) each other, and the semiconductor dies 100A of the wafer W1 being formed in different and individual device regions DR1 are electrically independent from (e.g., electrically isolated from) each other. As shown in FIG. 16, the connecting structures 118 and the connecting structure 250 are bonded to each other by a one-to-one configuration, for example. In other words, in the vertical projection (e.g., the X-Y plane), each connecting structure 118 is overlapped with only one respective one connecting structure 250, along the direction Z. Owing to the configuration of the connecting structures 118 (with the pitches P3) and the connecting structures 250 (with the pitches P4), the overall routability at the interface of the semiconductor dies 20 and 100A of the semiconductor device 20000A is greatly improved. As shown in FIG. 16, the wafer W1 of the semiconductor device 20000A may be considered as a first tier T1 of the semiconductor device 20000A, and the wafer W3 of the semiconductor device 20000A may be considered as a second tier T2 of the semiconductor device 20000A, where the connecting structure 108 may be referred to as conductive terminals or conductor connectors of the semiconductor device 20000A for further electrical connections to external components.

The insulating encapsulation 300 may be made of a dielectric material (such as an oxide (e.g., silicon oxide), a nitride (e.g., silicon nitride), tetra-ethyl-ortho-silicate (TEOS), or the like) or any suitable insulating materials for gap fill, and may be formed by deposition (such as a CVD process). Alternatively, the insulating encapsulation 300 may be a molding compound, a molding underfill, a resin (such as epoxy-based resin), or the like, which may be formed by a molding process. The molding process may include a compression molding process or a transfer molding process. The insulating encapsulation 300 may include polymers (such as epoxy resins, phenolic resins, silicon-containing resins, or other suitable resins) or other suitable materials. Alternatively, the insulating encapsulation 300 may include an acceptable insulating encapsulation material. In some embodiments, the insulating encapsulation 300 further includes inorganic filler or inorganic compound (e.g., silica, clay, and so on) which can be added therein to optimize coefficient of thermal expansion (CTE)of the insulating encapsulation 300. The disclosure is not limited thereto.

However, the disclosure is not limited thereto. Alternatively, a semiconductor device of the disclosure may be formed in a stacking structure of chiplet-form. In some embodiments, a dicing (singulation) process is performed to cut through the wafer W1 and the wafer W3 of the stacking structure of the semiconductor device 20000A so to form a plurality of separated and individual semiconductor devices 2000A, see FIGS. 16 and 17. Referring to FIG. 17, only one semiconductor device 2000A is shown for illustrative purposes and simplicity. In one embodiment, the dicing (singulation) process is a wafer dicing process including mechanical blade sawing or laser cutting, however the disclosure is not limited thereto. In some embodiments, each semiconductor device 2000A includes one semiconductor die 100A (e.g., located in the device regions DR1 of the wafer W1), one semiconductor die 20 stacked thereon and an insulating encapsulation 300 disposed on the semiconductor die 20 and covering the semiconductor die 100A exposed by the semiconductor die 20, where the semiconductor die 20 is electrically communicated and electrically connected to the semiconductor die 100A by connecting the connecting structures 250 and the connecting structures 118. As shown in FIG. 17, a sidewall SW20 of the semiconductor die 20 may be covered by a sidewall SW300 of the insulating encapsulation 300, where the sidewall SW300 of the insulating encapsulation 300 and a sidewall SW100 of the semiconductor die 100A may together constitute a sidewall of the semiconductor device 2000A. For example, the semiconductor die 200A of the semiconductor device 2000A may be considered as a first tier T1 of the semiconductor device 2000A, and the semiconductor die 20 and the insulating encapsulation 300 of the semiconductor device 2000A may be considered as a second tier T2 of the semiconductor device 2000A, where the connecting structure 108 may be referred to as conductive terminals or conductor connectors of the semiconductor device 2000A for further electrical connections to external components. As shown in FIG. 17, the sidewall SW300 of the insulating encapsulation 300 is aligned with the sidewall SW100 of the semiconductor die 100A, for example.

In the embodiments of the semiconductor devices 20000A and 2000A, the through vias 111 are electrically coupled to the connecting structure 118 through the interconnect 117. However, the disclosure is not limited thereto, alternatively, the interconnect 117 can be omitted, see the semiconductor devices 20000B (including a first tier T1 (with a wafer W1’ including a plurality of semiconductor dies 100B) and a second tier T2 (with a wafer W3 including a plurality of semiconductor dies 20 and an insulating encapsulation 300)) and 2000B (including a first tier T1 (with a semiconductor die 100B) and a second tier T2 (with a semiconductor die 20 and an insulating encapsulation 300)). The semiconductor device 20000B of FIG. 18 is similar to the semiconductor device 20000A of FIG. 16 and the semiconductor device 2000B of FIG. 19 is similar to the semiconductor device 2000A of FIG. 17, a difference is that, in the semiconductor devices 20000B and 2000B, the through vias 111 of the wafer W1’ (or saying the semiconductor die 100B) are electrically coupled to the connecting structure 118 through direct contacts, where the through vias 111 are in physical contact with the connecting structure 118.

In the embodiments of the semiconductor devices 20000A and 2000A, the pitch P2 between two immediately adjacent through vias 111 is considered as the large pitch. However, the disclosure is not limited thereto, alternatively, a pitch between two immediately adjacent through vias 111 can be a fine (or small) pitch, see the semiconductor devices 20000C (including a first tier T1 (with a wafer W1” including a plurality of semiconductor dies 100C) and a second tier T2 (with a wafer W3 including a plurality of semiconductor dies 20 and an insulating encapsulation)) and 2000C (including a first tier T1 (with a semiconductor die 100C) and a second tier T2 (with a semiconductor die 20 an insulating encapsulation)). The semiconductor device 20000C of FIG. 20 is similar to the semiconductor device 20000A of FIG. 16 and the semiconductor device 2000C of FIG. 21 is similar to the semiconductor device 2000A of FIG. 17, a difference is that, in the semiconductor devices 20000C and 2000C, the through vias 111 has a pitch P5, where the pitch P5 between two immediately adjacent through vias 111 may be considered as a fine (or small) pitch being less than or substantially equal to 10μm and greater than 0μm, in some embodiments. In a non-limiting example, the pitch P5 may be substantially equal to 6μm.

Similarly, in the embodiments of the semiconductor devices 20000C and 2000C, the through vias 111 are electrically coupled to the connecting structure 118 through the interconnect 117. However, the disclosure is not limited thereto, alternatively, the interconnect 117 can be omitted, see the semiconductor devices 20000D (including a first tier T1 (with a wafer W1”’ including a plurality of semiconductor dies 100D) and a second tier T2 (with a wafer W3 including a plurality of semiconductor dies 20 and an insulating encapsulation 300)) and 2000D (including a first tier T1 (with a semiconductor die 100D) and a second tier T2 (with a semiconductor die 20 and an insulating encapsulation 300)). The semiconductor device 20000D of FIG. 22 is similar to the semiconductor device 20000C of FIG. 20 and the semiconductor device 2000D of FIG. 23 is similar to the semiconductor device 2000C of FIG. 21, a difference is that, in the semiconductor devices 20000D and 2000D, the through vias 111 are electrically coupled to the connecting structure 118 through direct contacts, where the through vias 111 are in physical contact with the connecting structure 118.

In the embodiments of which the semiconductor devices 2000A-2000D, 20000A-20000D, the semiconductor die (e.g., 20) of the second tier T2 is not accessibly revealed by the insulating encapsulation 300. However, the disclosure is not limited thereto; alternatively, the semiconductor die (e.g., 20) of the second tier T2 may be accessibly revealed by the insulating encapsulation 300, see FIG. 24. The semiconductor device 2000A’ of FIG. 24 is similar to the semiconductor device 2000A of FIG. 17, a difference is that, in the semiconductor devices 2000A’, the back side S20b of the semiconductor die 20 is accessibly revealed by the surface S300t of the insulating encapsulation 300.

Referring to FIG. 24, a third planarization process may be performed on the insulating encapsulation 300 to expose the semiconductor die 20. For example, a portion of the insulating encapsulation 300 is removed, where the surface S300t of the insulating encapsulation 300 accessibly reveals the semiconductor dies 20. For example, the surface S300t of the insulating encapsulation 300 is substantially level with the back side S20b of the semiconductor die 20. In other words, the surface S300t of the insulating encapsulation 300 is substantially coplanar to the back side S20b of the semiconductor die 20.

In some embodiments, after the third planarization process, a cleaning step may be optionally performed to clean and remove the residue generated from the third planarization process. However, the disclosure is not limited thereto, and the third planarization process may be performed through any other suitable method. In addition, during the third planarization process, a portion of the substrate 210 of the semiconductor die 20 may also be slightly removed. The disclosure is not limited thereto.

In the embodiments of which the semiconductor devices 1000A-1000D, 2000A-2000D, 2000A’, 10000A-10000D, 20000A-20000D and/or their modifications, the semiconductor die (e.g., 100A, 100B, 100C, or 100D) of the first tier T1 and the semiconductor die (e.g., 20) of the second tier T2 are overlapped with one another by a one-to-one configuration in the direction Z. However, the disclosure is not limited thereto; alternatively, the semiconductor die (e.g., 100A, 100B, 100C, or 100D) of the first tier T1 and the semiconductor die (e.g., 20) of the second tier T2 may be overlapped with one another by a multiple-to-one configuration in the direction Z. Alternatively, the semiconductor die (e.g., 100A, 100B, 100C, or 100D) of the first tier T1 and the semiconductor die (e.g., 20) of the second tier T2 may be overlapped with one another by a multiple-to-multiple configuration in the direction Z. Or, the semiconductor die (e.g., 100A, 100B, 100C, or 100D) of the first tier T1 and the semiconductor die (e.g., 20) of the second tier T2 may be overlapped with one another by a one-to-multiple configuration, in the direction Z. The disclosure is not limited thereto.

The semiconductor device 1000A-1000D, 2000A-2000D, 2000A’, 10000A-10000D, 20000A-20000D or the modifications thereof may be further mounted onto another external electronical component, for example, mounted onto a circuit structure, such as a mother board, a package substrate, a printed circuit board (PCB), a printed wiring board, and/or other carrier that is capable of carrying integrated circuits. For a non-limiting example, semiconductor device 1000A-1000D, 2000A-2000D, 2000A’, 10000A-10000D, 20000A-20000D or the modifications thereof may be or may be part of an integrated Fan-Out (InFO) package, an InFO package having a Package-on-Package (PoP) structure, a chip-on-wafer-on-substrate (CoWoS) package, a flip chip package of an InFO package, or the like. The disclosure is not limited thereto.

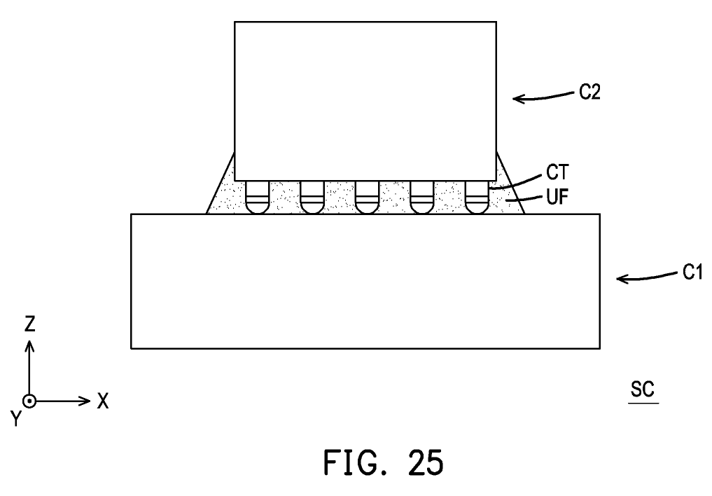

FIG. 25 is a schematic cross-sectional view showing an application of a semiconductor structure in accordance with some embodiments of the disclosure. The elements similar to or substantially the same as the elements described previously will use the same reference numbers, and certain details or descriptions (e.g., the materials, formation processes, positioning configurations, electrical connections, etc.) of the same elements would not be repeated herein.

Referring to FIG. 25, in some embodiments, a component assembly SC including a first component C1 and a second component C2 disposed over the first component C1 is provided. The first component C1 may be or may include a circuit structure, such as a mother board, a package substrate, another PCB, a printed wiring board, an interposer, and/or other carrier that is capable of carrying integrated circuits. In some embodiments, the second component C2 mounted on the first component C1 is similar to one of the semiconductor devices 1000A-1000D, 2000A-2000D, 2000A’, 10000A-10000D, 20000A-20000D or the modifications thereof. In a non-limiting example, one or more semiconductor device (e.g., one or multiple semiconductor devices 1000A-1000D, 2000A-2000D, 2000A’, 10000A-10000D, 20000A-20000D and/or the modifications thereof) may be electrically coupled to the first component C1 through a plurality of terminals CT. The terminals CT may be the connecting structures 108 as previously described.

In some embodiments, an underfill UF is formed between the gap of the first component C1 and the second component C2 to at least laterally cover the terminals CT. Alternatively, the underfill UF is omitted. The underfill UF may be any acceptable material, such as a polymer, epoxy resin, molding underfill, or the like, for example. In one embodiment, the underfill may be formed by underfill dispensing, a capillary flow process, or any other suitable method. Owing to the underfill UF, a bonding strength between the first component C1 and the second component C2 is enhanced.

In a semiconductor device of the disclosure, owing to the bonding structure, a bonding layer or a connecting layer of the first tier T1 (or saying the wafer W1/the semiconductor die 100A-100D) such as the connecting structures 118, a proper electrical connection between different tiers can be easily obtained and ensured. In addition, the presence of the interconnect 117 of the first tier T1 may provide further routability to ensure the electrical connection between different tiers such as the first tier (e.g., T1) and the second tier (e.g., T2).

In accordance with some embodiments, a semiconductor device includes a first tier and a second tier. The first tier includes a semiconductor die, where the semiconductor die includes a plurality of first connecting structures distributed over a non-active side of the semiconductor die. The second tier is disposed over the first tier and includes a memory die, the memory die includes a plurality of second connecting structures distributed over an active side of the memory die. The plurality of first connecting structures are connected to the plurality of second connecting structures in a one-to-one configuration, and the first tier is electrically coupled to the second tier.

In accordance with some embodiments, a semiconductor device includes a semiconductor die and at least one memory module. The semiconductor die has a first front side and a first back side opposite to the first front side, and includes a plurality of first connecting structures distributed on the first front side, a plurality of second connecting structures distributed on the first back side and a plurality of through vias electrically coupled to the plurality of first connecting structures and the plurality of second connecting structures. The at least one memory module is disposed on and electrically coupled to the semiconductor die, where the at least one memory module includes a die stack structure having a second front side and a second back side opposite to the second front side and a plurality of third connecting structures distributed on the second front side. The at least one memory module is connected to the semiconductor die in a face-to-back configuration, and a metal-to-metal bonding interface is between the plurality of second connecting structures and the plurality of third connecting structures.

In accordance with some embodiments, a method of manufacturing a semiconductor device includes the following steps: providing a first wafer comprising a plurality of semiconductor dies, wherein a back-side of the first wafer comprises a plurality of first connecting structures; providing a plurality of memory dies, wherein front-sides of the plurality of memory dies individually comprising a plurality of second connecting structures; and bonding the plurality of memory dies to the first wafer by connecting the plurality of first connecting structures to the plurality of second connecting structures in a one-to-one configuration, wherein the plurality of memory dies are electrically coupled to the plurality of semiconductor dies.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor device, comprising:
a semiconductor die, comprising:
a first substrate having a first side and a second side opposite to the first side, the second side being closer to a non-active side of the semiconductor die than the first side is;
a first interconnect, disposed over the first side of the first substrate;
a plurality of through vias, penetrating through the first substrate and electrically coupled to the first interconnect;
a plurality of first connecting structures, disposed over the first side of the first substrate and electrically coupled to the plurality of through vias through the first interconnect, a first pitch being between two adjacent first connecting structures of the plurality of first connecting structures; and
a plurality of second connecting structures, disposed over the second side of the first substrate and electrically coupled to the plurality of through vias, a second pitch being between two adjacent second connecting structures of the plurality of second connecting structures, wherein the first substrate is disposed between the plurality of second connecting structures and the plurality of first connecting structures; and
a memory die, disposed over and electrically coupled to the semiconductor die, and comprising a plurality of third connecting structures distributed over an active side of the memory die, a third pitch being between two adjacent third connecting structures of the plurality of third connecting structures, wherein the plurality of third connecting structures are connected to the plurality of second connecting structures in a one-to-one configuration.

2. The semiconductor device of claim 1, wherein the second pitch and the third pitch are greater than the first pitch.

3. The semiconductor device of claim 1, wherein the second pitch and the third pitch are less than a pitch being between two adjacent through vias of the plurality of through vias.

4. The semiconductor device of claim 1, wherein the second pitch and the third pitch are substantially equal to a pitch being between two adjacent through vias of the plurality of through vias.

5. The semiconductor device of claim 1, wherein the second pitch and the third pitch are greater than a pitch being between two adjacent through vias of the plurality of through vias.

6. The semiconductor device of claim 1, further comprising:
a second interconnect, disposed over the second side of the first substrate, wherein the plurality of through vias are electrically coupled to the plurality of second connecting structures through the second interconnect, and the second interconnect is between the first substrate and the plurality of second connecting structures.

7. The semiconductor device of claim 1, wherein the plurality of through vias protrude away from the first side and the second side of the first substrate.

8. The semiconductor device of claim 1, wherein sidewalls of the memory die are substantially aligned with sidewalls of the semiconductor die, in a cross-section of the semiconductor device along a stacking direction of the memory die and the semiconductor die.

9. A semiconductor device, comprising:
a semiconductor die, comprising:
a first substrate having a first side and a second side opposite to the first side, the second side being closer to a non-active side of the semiconductor die than the first side is;
a first interconnect, disposed over the first side of the first substrate;
a plurality of through vias, penetrating through the first substrate and electrically coupled to the first interconnect;
a plurality of first connecting structures, disposed over the first side of the first substrate and electrically coupled to the plurality of through vias through the first interconnect, a first pitch being between two adjacent first connecting structures of the plurality of first connecting structures; and
a plurality of second connecting structures, disposed over the second side of the first substrate and electrically coupled to the plurality of through vias, a second pitch being between two adjacent second connecting structures of the plurality of second connecting structures, wherein the first substrate is disposed between the plurality of second connecting structures and the plurality of first connecting structures;
a memory die, disposed over and electrically coupled to the semiconductor die, and comprising a plurality of third connecting structures distributed over an active side of the memory die, a third pitch being between two adjacent third connecting structures of the plurality of third connecting structures, wherein the plurality of third connecting structures are connected to the plurality of second connecting structures in a one-to-one configuration; and
an insulating encapsulation, disposed over the semiconductor die and encapsulating the memory die.

10. The semiconductor device of claim 9, wherein the second pitch and the third pitch are greater than the first pitch.

11. The semiconductor device of claim 9, wherein the second pitch and the third pitch are less than a pitch being between two adjacent through vias of the plurality of through vias.

12. The semiconductor device of claim 9, wherein the second pitch and the third pitch are substantially equal to a pitch being between two adjacent through vias of the plurality of through vias.

13. The semiconductor device of claim 9, wherein the second pitch and the third pitch are greater than a pitch being between two adjacent through vias of the plurality of through vias.

14. The semiconductor device of claim 9, further comprising:
a second interconnect, disposed over the second side of the first substrate, wherein the plurality of through vias are electrically coupled to the plurality of second connecting structures through the second interconnect, and the second interconnect is between the first substrate and the plurality of second connecting structures.

15. The semiconductor device of claim 9, wherein the plurality of through vias protrude away from the first side and the second side of the first substrate.

16. The semiconductor device of claim 9, wherein sidewalls of the insulating encapsulation are substantially aligned with sidewalls of the semiconductor die, in a cross-section of the semiconductor device along a stacking direction of the memory die and the semiconductor die.

17. The semiconductor device of claim 9, wherein a surface of the memory die is accessibly exposed by the insulating encapsulation.

18. A method, comprising:
providing a first device substrate comprising a plurality of semiconductor dies, wherein a back-side of the first device substrate comprises a plurality of first connecting structures and a first bonding dielectric layer laterally covering the plurality of first connecting structures;
providing a second device substrate comprising a plurality of memory dies, wherein a front-side of the second device substrate comprises a plurality of second connecting structures and a second bonding dielectric layer laterally covering the plurality of second connecting structures;
bonding the second device substrate to the first device substrate by connecting the plurality of first connecting structures to the plurality of second connecting structures in a one-to-one configuration and connecting the first bonding dielectric layer to the second bonding dielectric layer, wherein the plurality of memory dies are electrically coupled to the plurality of semiconductor dies; and
performing a singulation process to cut through the first device substrate and the second device substrate.

19. The method of claim 18, wherein bonding the second device substrate to the first device substrate is performed by a direct metal-to-metal bonding and a direct dielectric-to-dielectric bonding.

20. The method of claim 18, wherein the plurality of semiconductor dies comprises a plurality of through vias formed therein and having a pitch being between two adjacent through vias of the plurality of through vias,
wherein the second pitch and the third pitch are less than or substantially equal to the pitch.
